(19) United States
(12) Patent Application Publication
(10) Pub. No.: US 2026/0268862 A1
(43) Pub. Date: Sep. 10, 2026

(54) ELECTRONIC DEVICE INCLUDING DISPLAY DEVICE AND OPERATION METHOD OF SAME

(71) Applicant: SAMSUNG ELECTRONICS CO., LTD., Suwon-si (KR)

(72) Inventors: Kiwoo Kim, Suwon-si (KR); Seungwon Seok, Suwon-si (KR); Changmin Keum, Suwon-si (KR); Yeonghyeon Kim, Suwon-si (KR)

(73) Assignee: SAMSUNG ELECTRONICS CO., LTD., Suwon-si (KR)

(21) Appl. No.: 19/659,470

(22) Filed: Apr. 27, 2026

Related U.S. Application Data
(63) Continuation of application No. PCT/KR2026/095037, filed on Jan. 22, 2026.

(30) Foreign Application Priority Data
Jan. 22, 2025 (KR) 10-2025-0009826
Dec. 29, 2025 (KR) 10-2025-0212927

(51) Int. Cl. G09G 3/3291

(52) U.S. Cl. CPC G09G 3/3291; G09G 2300/0426; G09G 2300/0439; G09G 2320/0646; G09G 2340/04; G09G 2360/142

(57) ABSTRACT

An electronic device including: a display device; memory storing instructions; and at least one processor including processing circuitry, wherein the display device includes: a pixel layer including: light-emitting pixels; and light-receiving pixels including: first-group light-receiving pixels; and second-group light-receiving pixels; and a lens layer on the pixel layer and including lenses respectively corresponding to the light-receiving pixels, and wherein the at least one processor individually or collectively executes the instructions to cause the electronic device to: obtain, by applying a first driving voltage to the first-group light-receiving pixels and applying a second driving voltage having a voltage value different from a voltage value of the first driving voltage to the second-group light-receiving pixels: first light-reception signals from the first-group light-receiving pixels; and second light-reception signals from second-group light-receiving pixels; and generate an HDR image based on the first light-reception signals and the second light-reception signals.

### CROSS-REFERENCE TO RELATED APPLICATIONS

This application is a continuation of International Application No. PCT/KR2026/095037 designating the United States, filed on Jan. 22, 2026, in the Korean Intellectual Property Receiving Office and claiming priority to Korean Patent Application No. 10-2025-0009826, filed on Jan. 22, 2025, and Korean Patent Application No. 10-2025-0212927, filed on Dec. 29, 2025, in the Korean Intellectual Property Office, the disclosures of each of which are incorporated by reference herein in their entireties.

### BACKGROUND

### 1. Field

The disclosure relates to an electronic device including a display device and an operation method of the electronic device. In particular, the disclosure relates to an electronic device including a display device configured to display an output image and obtain a sensing image corresponding to a surrounding environment, and an operation method of the electronic device.

### 2. Description of Related Art

With the advancement of electronic technology, various types of electronic devices have been developed and widely distributed. In addition, advancements in camera technology have enabled cameras to be integrated into electronic devices.

Related-art electronic devices are equipped with a display for displaying images, thereby providing various images to a user.

Furthermore, a user may capture an image through a camera included in an electronic device, and technology has been utilized in which the electronic device displays the captured image or stores and manages the image therein.

Moreover, an electronic device including both a display and a camera may obtain a user input based on an image obtained through the camera, and control an image displayed on the display based on the obtained user input.

### SUMMARY

One or more embodiments of the present disclosure may provide an electronic device including: a display device; memory storing instructions; and at least one processor including processing circuitry, wherein the display device includes: a pixel layer including: a plurality of light-emitting pixels; and a plurality of light-receiving pixels including: first-group light-receiving pixels; and second-group light-receiving pixels; and a lens layer on the pixel layer and including a plurality of lenses respectively corresponding to the plurality of light-receiving pixels, and wherein the at least one processor individually or collectively executes the instructions to cause the electronic device to: obtain, by applying a first driving voltage to the first-group light-receiving pixels and applying a second driving voltage having a voltage value different from a voltage value of the first driving voltage to the second-group light-receiving pixels: first light-reception signals from the first-group light-receiving pixels; and second light-reception signals from second-group light-receiving pixels; and generate a high dynamic range image based on the obtained first light-reception signals and the obtained second light-reception signals.

One or more embodiments of the present disclosure may provide a method of operating an electronic device, wherein the display device includes: a pixel layer including a plurality of light-emitting pixels and a plurality of light-receiving pixels; and a lens layer on the pixel layer and including a plurality of lenses respectively corresponding to the plurality of light-receiving pixels, including: obtaining, by applying a first driving voltage to the first-group light-receiving pixels and applying a second driving voltage having a voltage value different from a voltage value of the first driving voltage to the second-group light-receiving pixels: first light-reception signals from first-group light-receiving pixels among the plurality of light-receiving pixels; and second light-reception signals from second-group light-receiving pixels among the plurality of light-receiving pixels; and generating a high dynamic range image based on the obtained first light-reception signals and the obtained second light-reception signals.

### BRIEF DESCRIPTION OF DRAWINGS

The disclosure may be understood with a combination of the following detailed descriptions and the accompanying drawings, wherein reference numbers refer to structural elements.

FIG. 1 is a diagram for describing an operation of an electronic device according to one or more embodiments of the disclosure.

FIG. 2 is a block diagram for describing a configuration of an electronic device according to one or more embodiments of the disclosure.

FIG. 3 is a block diagram for describing a configuration of a display device according to one or more embodiments of the disclosure.

FIG. 4 is a diagram for describing a configuration of a display device according to one or more embodiments of the disclosure.

FIG. 5 is a diagram for describing an arrangement of a plurality of components included in a display device, according to one or more embodiments of the disclosure.

FIG. 6 is a diagram for describing a circuit layer and a light-emitting layer, according to one or more embodiments of the disclosure.

FIG. 7 is a diagram for describing an arrangement of a plurality of components included in a display device, according to one or more embodiments of the disclosure.

FIG. 8 is a flowchart for describing an operation, performed by an electronic device, of generating a high dynamic range (HDR) image, according to one or more embodiments of the disclosure.

FIG. 9 is a diagram for describing an operation, performed by an electronic device, of obtaining an HDR image, according to one or more embodiments of the disclosure.

FIG. 10 is a graph showing I-V characteristic curves of a light-receiving pixel, according to one or more embodiments of the disclosure.

FIG. 11 illustrates examples of images obtained through a plurality of light-receiving pixels, according to one or more embodiments of the disclosure.

FIG. 12 is a flowchart for describing an operation, performed by an electronic device, of generating a high-resolution image, according to one or more embodiments of the disclosure.

FIG. 13 is a diagram for describing an operation, performed by an electronic device, of obtaining a high-resolution image, according to one or more embodiments of the disclosure.

FIG. 14 is a flowchart for describing an operation, performed by an electronic device, of applying a driving voltage to light-receiving pixels, according to one or more embodiments of the disclosure.

FIG. 15 is a flowchart for describing an operation, performed by an electronic device, of generating an HDR image, according to one or more embodiments of the disclosure.

FIG. 16 is a diagram for describing an operation, performed by an electronic device, of obtaining a plurality of light-reception signals through time division of each frame, according to one or more embodiments of the disclosure.

FIG. 17 is a flowchart for describing an operation, performed by an electronic device, of generating an HDR image based on a plurality of light-reception signals, according to one or more embodiments of the disclosure.

FIG. 18 is a flowchart for describing an operation, performed by an electronic device, of generating an HDR image based on a plurality of light-reception signals, according to one or more embodiments of the disclosure.

FIG. 19 is a diagram for describing an operation, performed by an electronic device, of generating an HDR image based on a plurality of light-reception signals, according to one or more embodiments of the disclosure.

FIG. 20 is a diagram for describing a display device and a voltage control circuit, according to one or more embodiments of the disclosure.

FIG. 21 is a diagram for describing a display device and a voltage control circuit, according to one or more embodiments of the disclosure.

FIG. 22A is a diagram for describing a display device and a voltage control circuit, according to one or more embodiments of the disclosure.

FIG. 22B is a diagram for describing a display device and a voltage control circuit, according to one or more embodiments of the disclosure.

### DETAILED DESCRIPTION

Terms used herein will be briefly described, and then one or more embodiments of the disclosure will be described in detail.

Throughout the disclosure, unless specifically stated otherwise, the term “or” is inclusive and not exclusive. Therefore, unless explicitly indicated otherwise or the context indicates otherwise, “A or B” may indicate “A, B, or both”.

As used herein, the expression “at least one of a, b, or c” may refer to “a”, “b”, “c”, “a and b”, “a and c”, “b and c”, “a, b, and c”, or variations thereof.

The terms used in the disclosure have been selected from among general terms that are currently widely used as much as possible while considering functions in one or more embodiments of the disclosure, but these may vary depending on the intention of a person skilled in the art, precedents, or the emergence of new technologies. Also, in particular cases, the terms are discretionally selected by the applicant of the disclosure, in which case, the meaning of those terms will be described in detail in the corresponding description of one or more embodiments of the disclosure. Therefore, the terms used herein are not merely designations of the terms, but the terms are defined based on the meaning of the terms and content throughout the disclosure.

The singular expression may also include the plural meaning as long as it is not inconsistent with the context. All the terms used herein, including technical and scientific terms, may have the same meanings as those generally understood by those skilled in the art related to the specification.

Throughout the disclosure, when a part “includes” an element, it is to be understood that the part may additionally include other elements rather than excluding other elements as long as there is no particular opposing recitation. In addition, as used herein, the terms such as “ . . . er (or)”, “ . . . unit”, “ . . . module”, etc., denote a unit that performs at least one function or operation, which may be implemented as hardware or software or a combination thereof.

As used herein, the expression “configured to” may be interchangeably used with, for example, “suitable for”, “having the capacity to”, “designed to”, “adapted to”, “made to”, or “capable of”, depending on the context. The expression “configured to” may not imply only “specially designed to” in a hardware manner. Instead, in some circumstances, the expression “a system configured to” may mean that the system is “capable of” performing a function in conjunction with other devices or components. For example, “a processor configured (or set) to perform A, B, and C” may imply a dedicated processor (e.g., an embedded processor) for performing a corresponding operation or a general-purpose processor (e.g., central processing unit (CPU) or an application processor) capable of performing corresponding operations by executing one or more software programs stored in memory.

In addition, in the disclosure, it should be understood that when components are “connected” or “coupled” to each other, the elements may be directly connected or coupled to each other, but may alternatively be connected or coupled to each other with an element therebetween, unless specified otherwise.

In the specification, when a component (or a region, a layer, a portion, etc.) is referred to as being “on,” “connected to,” or “coupled to” another component, it means that it may be directly arranged on, connected to, or coupled to the other component, or a third component may be arranged therebetween.

In the disclosure, “directly arranged” may mean that no additional layer, film, region, plate, or the like is arranged between a portion, such as a layer, a film, a region, or a plate, and another portion. For example, “directly arranged” may mean arranging two layers or two members without using an additional member, such as an adhesive member, therebetween.

Furthermore, terms such as “below,” “at a lower side,” “above,” “at an upper side,” “on,” “on an upper surface,” or “on a lower surface” are used to describe the relationship of components illustrated in the drawings. These terms are relative concepts, and the directions or orientations described by these terms are based on the drawings.

It should be understood that blocks in each flowchart, and combinations of flowcharts may be performed by one or more computer programs including computer-executable instructions. The one or more computer programs may be all stored in a single memory unit, or may be divided and stored in a plurality of different memory units.

All functions or operations described herein may be performed by a single processor or a combination of processors.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, “about the same”, and/or “substantially the same”.

The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

Unless otherwise indicated, as used herein with regard to any plurality of a particular type of component, any two components of that type are considered “adjacent” or “adjacent to” one another so long as no other component of that type occupies a space between the two components. That is, the two components are considered adjacent each other if the two components are not separated from each other by an intervening component of that type.

Furthermore, although one or more embodiments may comprise the disclosed features as described herein—as well as additional features not specifically described—other embodiments may instead be completely free of non-disclosed elements. For example, non-disclosed elements may be completely omitted from one or more embodiments of the present disclosure.

Hereinafter, embodiments of the disclosure will be described in detail with reference to the accompanying drawings to allow those of skill in the art to easily carry out the embodiments. One or more embodiments of the disclosure may, however, be embodied in many different forms and should not be construed as being limited to the embodiment of the disclosure set forth herein. Furthermore, in the drawings, portions that are irrelevant to the description are omitted to clearly describe one or more embodiments of the disclosure, and like reference numerals are assigned to like elements throughout the disclosure.

Hereinafter, embodiments of the disclosure will be described in detail with reference to the drawings.

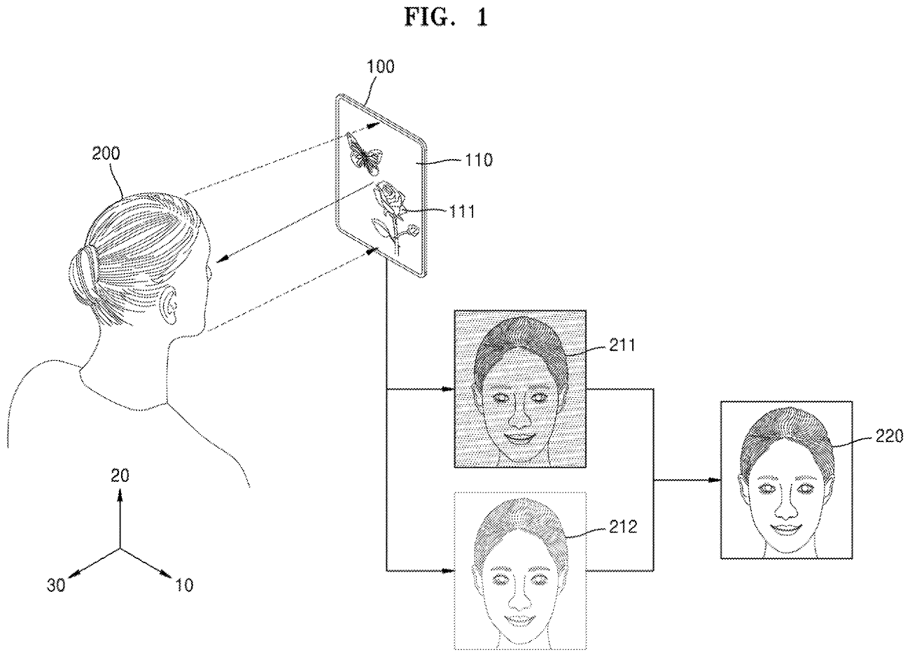

FIG. 1 is a diagram for describing an operation of an electronic device according to one or more embodiments of the disclosure.

FIG. 1 illustrates an electronic device 100 and a user 200 using the electronic device 100. Referring to FIG. 1, in one or more embodiments of the disclosure, the electronic device 100 may include a display device 110. The display device 110 may have a shape parallel to a plane defined by a first direction 10 and a second direction 20.

Although FIG. 1 illustrates that the electronic device 100 is a bar-type rigid electronic device, the disclosure is not limited thereto. In one or more embodiments of the disclosure, the electronic device 100 may be a foldable, rollable, or slidable electronic device. In this case, the display device 110 may have a shape that is bent or folded relative to a plane defined by the first direction 10 and the second direction 20.

Hereinafter, a normal direction substantially perpendicular to a plane defined by the first direction 10 and the second direction 20 is defined as a third direction 30. In the specification, the expression “in a plan view” may be construed as viewing in the third direction 30. In other words, the plan view may coincide with a surface defined by the first direction 10 and the second direction 20.

In one or more embodiments of the disclosure, the electronic device 100 may be implemented as various types of electronic devices, such as a smart phone, a laptop computer, a tablet personal computer (PC), a television, a mobile device, digital signage, or a head-mounted display device.

In one or more embodiments of the disclosure, the display device 110 may include a pixel layer including a plurality of light-emitting pixels. The electronic device 100 may display an image 111 by controlling the plurality of light-emitting pixels.

In one or more embodiments of the disclosure, the electronic device 100 may provide the image 111 to the user 200 by displaying the image 111 in the third direction 30 through the display device 110. A direction in which the image 111 is displayed through the display device 110 may correspond to a front surface of the electronic device 100. Hereinafter, the image 111 displayed through the display device 110 is referred to as an output image 111.

In one or more embodiments of the disclosure, the display device 110 may also include a pixel layer including a plurality of light-receiving pixels. The electronic device 100 may sense the user 200 using the electronic device 100 through the plurality of light-receiving pixels to obtain a plurality of image data sets 211 and 212 corresponding to the user 200. The electronic device 100 may apply (e.g., simultaneously (in the disclosure, ‘simultaneously’ may include simultaneously for at least some of the time)) two or more driving voltages having different voltage values to the plurality of light-receiving pixels, to obtain the plurality of image data sets 211 and 212 respectively corresponding to the two or more driving voltages. The plurality of image data sets 211 and 212 may correspond to respective image data sets captured under different sensitivity conditions. For example, the plurality of image data sets 211 and 212 may include at least one of an image data set captured under a relatively high-sensitivity condition in a low-illuminance region or an image data set captured under a relatively low-sensitivity condition in a medium/high-illuminance region.

For example, the electronic device 100 may sense the user 200 through first-group light-receiving pixels to which a first driving voltage is applied, to obtain a first image data set 211 corresponding to the user 200. The electronic device 100 may sense the user 200 through second-group light-receiving pixels to which a second driving voltage different from the first driving voltage is applied, to obtain a second image data set 212 corresponding to the user 200.

However, the disclosure is not limited thereto, and the electronic device 100 may sense an environment surrounding the electronic device 100 (e.g., an object or a background around the electronic device 100) through the plurality of light-receiving pixels, to obtain a plurality of image data sets 211 and 212.

In one or more embodiments of the disclosure, the electronic device 100 may generate an image 220 based on the plurality of image data sets 211 and 212. Hereinafter, the image 220 generated through the display device 110 is referred to as a sensing image 220.

For example, the sensing image 220 may be a high dynamic range (HDR) image. The electronic device 100 may generate the HDR image 220 by registering and fusing the plurality of image data sets 211 and 212 by using an HDR fusion algorithm. In the disclosure, the HDR image 220 may refer to an image generated based on the plurality of image data sets 211 and 212 obtained under different sensitivity conditions. Because the HDR image 220 may represent a brightness range (e.g., a bright region and/or a dark region) that is difficult to represent with an image data set obtained under a single sensitivity condition, the HDR image 220 may provide an extended dynamic range. Accordingly, through the plurality of light-receiving pixels to which a plurality of different driving voltages are applied, the electronic device 100 may obtain the sensing image 220 in which a bright region and a dark region are simultaneously represented with high precision.

According to one or more embodiments of the disclosure, the electronic device 100 may obtain a plurality of image data sets corresponding to the same scene obtained under different sensitivity conditions by applying different driving voltages to the light-receiving pixels in the same time period. Accordingly, the electronic device 100 may obtain the sensing image 220 (e.g., an HDR image) free of ghosting artifacts even for a moving subject. In addition, the electronic device 100 may implement the sensing image 220 (e.g., an HDR image) at a relatively high speed.

According to one or more embodiments of the disclosure, the electronic device 100 may obtain a plurality of image data sets corresponding to the same scene obtained under different sensitivity conditions by controlling sensitivity through a driving voltage without adjusting an exposure time. Accordingly, the electronic device 100 does not need to additionally provide a separate configuration for controlling the exposure time, and thus, its structure may be simplified. Furthermore, while setting a long exposure time for low-illuminance imaging may result in sensing delays and ghosting artifacts for a moving subject, the electronic device 100 according to one or more embodiments of the disclosure may prevent sensing delays and the occurrence of ghosting artifacts by controlling sensitivity through a driving voltage.

In one or more embodiments of the disclosure, the display device 110 may include a lens layer arranged on a pixel layer and including a plurality of lenses respectively corresponding to the plurality of light-receiving pixels. In one or more embodiments of the disclosure, the lens layer may be arranged on an upper surface of the pixel layer with respect to the third direction 30.

In one or more embodiments of the disclosure, the plurality of lenses in the lens layer may focus light entering the display device 110 from the outside onto the plurality of light-receiving pixels.

In addition, in one or more embodiments of the disclosure, the display device 110 may include an optical layer arranged between the pixel layer and the lens layer. Light provided to the display device 110 from the outside may be provided to the plurality of light-receiving pixels through the plurality of lenses and the optical layer.

Here, the thickness of the optical layer may be determined such that the plurality of light-receiving pixels are located at the focal length of each of the plurality of lenses. Through the optical layer, the focal point of each of the plurality of lenses may coincide with the corresponding one of the plurality of light-receiving pixels.

Accordingly, a sharp sensing image 220 may be obtained through the display device 110. In one or more embodiments of the disclosure, the electronic device 100 may obtain the sensing image 220 by sensing not only an object in contact with the display device 110 (e.g., an object touching the display device 110 or a part of a human body region in contact with the display device 110) but also an object spaced apart from the display device 110 by a certain distance (e.g., the user 200 viewing the displayed image 111 through the display device 110).

In one or more embodiments of the disclosure, the electronic device 100 may obtain the sensing image 220 by sensing a user or a surrounding environment through the display device 110, even without a separate component such as a camera or an infrared (IR) sensor.

In one or more embodiments of the disclosure, the electronic device 100 may perform an operation of displaying the output image 111 to the user 200 through the display device 110, perform an operation of recognizing the user 200 to obtain the sensing image 220, or simultaneously perform both operations. Through this, the electronic device 100 may obtain, through the sensing image 220, a motion, an expression, or an instruction of the user 200 viewing the output image 111, to perform an interaction with the user 200. According to one or more embodiments of the disclosure, by obtaining the sensing image 220 in which a bright region and a dark region are simultaneously represented with high precision, the electronic device 100 may improve accuracy in performing an interaction with the user 200.

Alternatively, in one or more embodiments of the disclosure, the electronic device 100 may utilize the sensing image 220 obtained through the display device 110 for ambient light adaptation (e.g., brightness adjustment for an output image, color temperature correction, etc.). According to one or more embodiments of the disclosure, by obtaining the sensing image 220 in which a bright region and a dark region are simultaneously represented with high precision, to improve accuracy of illuminance sensing of the surrounding environment, the electronic device 100 may display an output image that preserves readability and visibility according to the surrounding environment.

Hereinafter, a configuration of the display device 110 included in the electronic device 100 and an operation of the electronic device 100 will be described in detail.

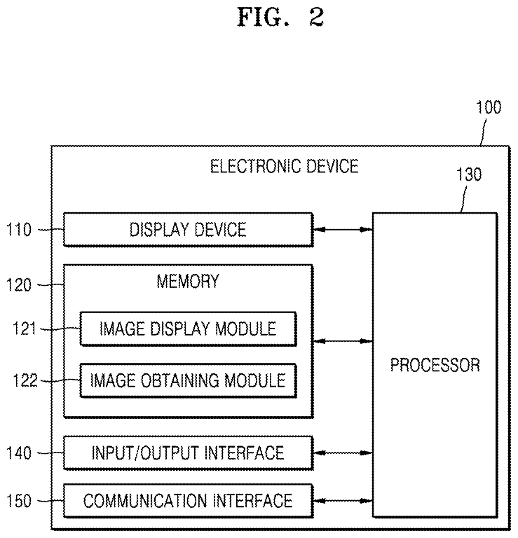

FIG. 2 is a block diagram for describing a configuration of an electronic device according to one or more embodiments of the disclosure.

Referring to FIGS. 1 and 2, in one or more embodiments of the disclosure, the electronic device 100 may include the display device 110, memory 120, at least one processor 130, an input/output interface 140, and a communication interface 150.

However, not all components illustrated in FIG. 2 are essential components. The electronic device 100 may be implemented with more components than those illustrated in FIG. 2, or may be implemented with fewer components than the shown components.

The display device 110, the memory 120, the at least one processor 130, the input/output interface 140, and the communication interface 150 included in the electronic device 100 may be electrically connected to each other.

In one or more embodiments of the disclosure, as the at least one processor 130 controls the display device 110, the electronic device 100 may display an image. In addition, as the at least one processor 130 controls the display device 110, the electronic device 100 may sense light provided from the surroundings to obtain an image.

In one or more embodiments of the disclosure, the display device 110 may include a plurality of light-emitting pixels. The plurality of light-emitting pixels included in the display device 110 may include organic light-emitting diodes. However, the disclosure is not limited thereto, and the plurality of light-emitting pixels included in the display device 110 may include inorganic light-emitting diodes. However, the disclosure is not limited thereto, and it is obvious that the display device 110 may include other types of light-emitting pixels capable of displaying an image (e.g., a combination of a backlight and a color filter).

In one or more embodiments of the disclosure, the display device 110 may include a plurality of light-receiving pixels. The plurality of light-receiving pixels included in the display device 110 may include inorganic photodiodes, for example, thin-film transistor (TFT) photodiodes. The TFT photodiode may include an amorphous silicon PIN diode or an oxide photodiode.

However, the disclosure is not limited thereto, and the plurality of light-receiving pixels included in the display device 110 may include organic photodiodes.

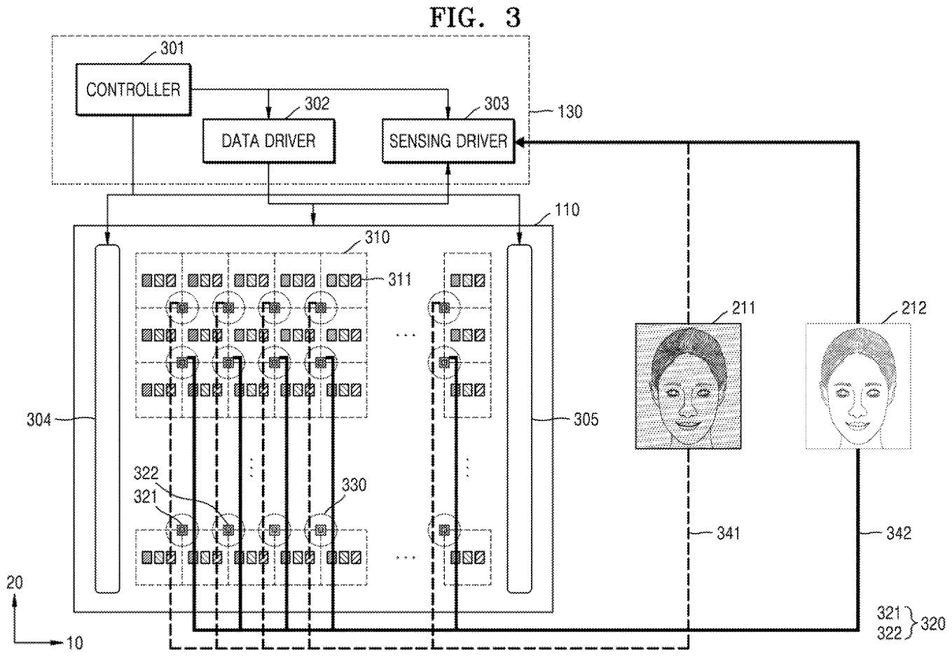

Components included in the display device 110 and an arrangement of the components in the display device 110 will be described below with reference to FIGS. 3 to 7E.

In one or more embodiments of the disclosure, the memory 120 may store instructions, a data structure, and program code that are readable by the at least one processor 130. In one or more embodiments of the disclosure, one or more memory units may be provided. By executing instructions (or code) of a program stored in the memory 120, the at least one processor 130 may implement operations performed by the electronic device 100.

In one or more embodiments of the disclosure, the memory 120 may include at least one of flash memory-type memory, hard disk-type memory, multimedia card micro-type memory, card-type memory (e.g., SD or XD memory), random-access memory (RAM), static RAM (SRAM), read-only memory (ROM), electrically erasable programmable ROM (EEPROM), programmable ROM (PROM), mask ROM, flash ROM, a hard disk drive (HDD), or a solid-state drive (SSD).

In one or more embodiments of the disclosure, the memory 120 may be configured to be included in the at least one processor 130 rather than existing as a separate component.

In one or more embodiments of the disclosure, the memory 120 may store instructions or program code for performing functions or operations of the electronic device 100. Instructions, algorithms, data structures, program code, and application programs stored in the memory 120 may be implemented in a programming or scripting language, such as C, C++, Java, Python, or an assembler.

In one or more embodiments of the disclosure, the memory 120 may store various types of modules that may be used for performing operations of the electronic device 100.

In one or more embodiments of the disclosure, an image display module 121 and an image obtaining module 122 may be stored in the memory 120. However, not all modules illustrated in FIG. 2 are essential. More modules than those illustrated in FIG. 2 may be stored in the memory 120, or fewer modules than the shown modules may be stored.

In one or more embodiments of the disclosure, a ‘module’ included in the memory 120 may refer to a unit for processing a function or an operation performed by the at least one processor 130. A ‘module’ included in the memory 120 may be implemented as software such as instructions, algorithms, data structures, or program code.

In one or more embodiments of the disclosure, the image display module 121 may include instructions or program code associated with an operation or a function for displaying the output image 111 through the display device 110.

In one or more embodiments of the disclosure, the at least one processor 130 may execute instructions or program code of the image display module 121 to cause the electronic device 100 to display the output image 111 through the display device 110.

In one or more embodiments of the disclosure, the image obtaining module 122 may include instructions or program code associated with an operation or a function for obtaining the sensing image 220 through the display device 110. For example, the image obtaining module 122 may include instructions or program code associated with an operation or a function of obtaining, through a plurality of light-receiving pixels to which a plurality of different driving voltages are applied in accordance with respective positions (or regions) thereof, a plurality of image data sets respectively corresponding to the plurality of driving voltages, and obtaining the sensing image 220 based on the plurality of image data sets obtained.

In one or more embodiments of the disclosure, the at least one processor 130 may execute instructions or program code of the image obtaining module 122 to cause the electronic device 100 to obtain the sensing image 220 through the display device 110. For example, the at least one processor 130 may execute the instructions or program code of the image obtaining module 122 to cause the electronic device 100 to obtain, through a plurality of light-receiving pixels to which a plurality of different driving voltages are applied in accordance with respective positions (or regions) thereof, a plurality of image data sets respectively corresponding to the plurality of driving voltages, and obtain the sensing image 220 based on the plurality of image data sets obtained.

In one or more embodiments of the disclosure, the at least one processor 130 is a component for controlling a series of processes to cause the electronic device 100 to operate according to one or more embodiments of the disclosure described below, and may include one or more processors.

In one or more embodiments of the disclosure, the at least one processor 130 may include at least one of a central processing unit, a microprocessor, a graphics processing unit, an application processor, an application-specific integrated circuit (ASIC), a digital signal processor (DSP), a digital signal processing device (DSPD), a programmable logic device (PLD), a field-programmable gate array (FPGA), or a communication processor (CP), but is not limited thereto.

In one or more embodiments of the disclosure, the at least one processor 130 may be configured as circuitry such as a system-on-chip (SoC) or an integrated circuit (IC).

In one or more embodiments of the disclosure, the at least one processor 130 may execute various types of modules stored in the memory 120. The at least one processor 130 may individually or collectively execute at least one instruction constituting various types of modules stored in the memory 120.

By executing a program or at least one instruction stored in the memory 120, the at least one processor 130 may process data according to a predefined operation rule.

In one or more embodiments of the disclosure, the at least one processor 130 may include a plurality of processors. In one or more embodiments of the disclosure, at least one of a plurality of modules stored in the memory 120 may be executed by any one of the plurality of processors. Remaining modules among the plurality of modules stored in the memory 120 may be executed by another processor among the plurality of processors.

In one or more embodiments of the disclosure, the at least one processor 130 may include a controller 301 (see FIG. 3), a data driver 302 (see FIG. 3), and a sensing driver 303 (see FIG. 3). However, the disclosure is not limited thereto, and at least one component among the controller 301, the data driver 302, or the sensing driver 303 may be a component included in the display device 110.

In addition, in one or more embodiments of the disclosure, at least one component among a scan driver 304 or an emission driver 305 included in the display device 110 may be a component included in the at least one processor 130.

The controller 301, the data driver 302, the sensing driver 303, the scan driver 304, and the emission driver 305 will be described below with reference to FIG. 3.

In one or more embodiments of the disclosure, the input/output interface 140 may perform input/output operations with an external electronic device by using at least one of input/output methods including a High-Definition Multimedia Interface (HDMI) port, a Digital Visual Interface (DVI), a component jack, a personal computer (PC) port, or a Universal Serial Bus (USB) port. However, the disclosure is not limited to the above-described input/output methods.

In one or more embodiments of the disclosure, as the at least one processor 130 controls the input/output interface 140, the electronic device 100 may obtain an image signal and a scan control signal from an external electronic device or the like through the input/output interface 140.

In one or more embodiments of the disclosure, the electronic device 100 may display the output image 111 through the display device 110 based on the image signal obtained through the input/output interface 140.

In one or more embodiments of the disclosure, the communication interface 150 may perform data communication with an external server or an external electronic device by using at least one of data communication methods including, for example, wired local area network (LAN), wireless local area network (WLAN), Wi-Fi, Bluetooth, ZigBee, Wi-Fi direct (WFD), an Infrared Data Association (IrDA), Bluetooth Low Energy (BLE), near-field communication (NFC), wireless broadband internet (Wibro), Worldwide Interoperability for Microwave Access (WiMAX), Shared Wireless Access Protocol (SWAP), Wireless Gigabit Alliance (WiGig), and radio-frequency (RF) communication.

In one or more embodiments of the disclosure, as the at least one processor 130 controls the communication interface 150, the electronic device 100 may perform data communication with an external server or an external electronic device.

FIG. 3 is a block diagram for describing a configuration of a display device according to one or more embodiments of the disclosure.

Referring to FIGS. 1, 2, and 3, in one or more embodiments of the disclosure, the display device 110 included in the electronic device 100 is illustrated in FIG. 3. In addition, the controller 301, the data driver 302, and the sensing driver 303 among a plurality of components included in the display device 110 are illustrated in FIG. 3.

In one or more embodiments of the disclosure, the display device 110 may include the scan driver 304 and the emission driver 305.

In one or more embodiments of the disclosure, the display device 110 may include a display area in which the image 111 is displayed and a non-display area (e.g., a bezel area) that is adjacent to the display area and in which the image 111 is not displayed. In one or more embodiments of the disclosure, the scan driver 304 and the emission driver 305 may be arranged in the non-display area.

Although FIG. 3 illustrates the controller 301, the data driver 302, and the sensing driver 303 as separate components, the disclosure is not limited thereto. A single component may perform operations of two or more of the controller 301, the data driver 302, and the sensing driver 303.

In addition, although the scan driver 304 and the emission driver 305 are illustrated as separate components, it is obvious that operations of the scan driver 304 and the emission driver 305 may be performed by a single component. In addition, a component that performs operations of the scan driver 304 and the emission driver 305 may consist of two or more components and be arranged in the non-display area.

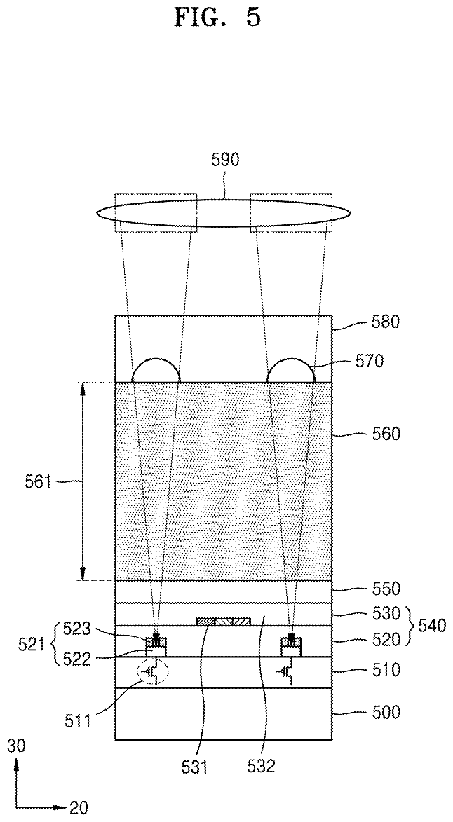

In one or more embodiments of the disclosure, the display device 110 may include a pixel layer 540 (see FIG. 5) including a plurality of light-emitting pixels 311 and a plurality of light-receiving pixels 320, and a lens layer 570 (see FIG. 5) including a plurality of lenses 330.

Here, the lens layer 570 may refer to an array of the plurality of lenses 330. That is, in a case where each of the plurality of lenses 330 is a micro-lens having a size on the order of micrometers, the lens layer may refer to a micro-lens array (MLA) representing an array of a plurality of micro-lenses.

In one or more embodiments of the disclosure, although FIG. 3 illustrates the plurality of light-emitting pixels 311, the plurality of light-receiving pixels 320, and the plurality of lenses 330 among the components included in the display device 110, the disclosure is not limited thereto, and it is obvious that the display device 110 may also include more components (e.g., a base layer 500 (see FIG. 5), an optical layer 560 (see FIG. 5)) than those illustrated in FIG. 3.

In one or more embodiments of the disclosure, each of the plurality of light-emitting pixels 311 may include a plurality of sub-pixels including light-emitting diodes that generate light of different colors. Here, the light-emitting diode may refer to a light-emitting element including the light-emitting diode.

In detail, each of the plurality of light-emitting pixels 311 may include a red sub-pixel including a red light-emitting diode that generates red-color light, a green sub-pixel including a green light-emitting diode that generates green-color light, and a blue sub-pixel including a blue-color diode that generates blue-color light.

However, the disclosure is not limited thereto, and each of the plurality of light-emitting pixels 311 may include at least one sub-pixel including light-emitting diodes that generate various combinations of color lights for displaying the output image 111.

Although not illustrated in FIG. 3, each of the plurality of light-emitting pixels 311 may be electrically connected to at least one transistor and at least one capacitor. The at least one transistor and the at least one capacitor electrically connected to each of the plurality of light-emitting pixels 311 may be referred to as a light-emitting pixel driving circuit.

In one or more embodiments of the disclosure, the light-emitting pixel driving circuit may be included in a circuit layer 510 (see FIG. 5) included in the display device 110. In one or more embodiments of the disclosure, the pixel layer 540 may be arranged on the circuit layer 510. The plurality of light-emitting pixels 311 included in the pixel layer 540 may be electrically connected to the light-emitting pixel driving circuits included in the circuit layer 510, respectively.

In one or more embodiments of the disclosure, the scan driver 304 and the emission driver 305 may also include a plurality of transistors and may be included in the circuit layer 510. However, the disclosure is not limited thereto, and in a case where the data driver 302 is included in the display device 110, the data driver 302 may also be included in the circuit layer 510.

In one or more embodiments of the disclosure, the display device 110 may include a plurality of first scan lines extending from the scan driver 304 in the second direction 20 and arranged to be spaced apart from each other in the first direction 10 intersecting the second direction 20. In addition, the display device 110 may include a plurality of emission lines extending from the emission driver 305 in a direction opposite to the second direction 20 and arranged to be spaced apart from each other in the first direction 10.

In one or more embodiments of the disclosure, the display device 110 may include a plurality of data lines extending from the data driver 302 in a direction opposite to the first direction 10 and arranged to be spaced apart from each other in the second direction 20.

In one or more embodiments of the disclosure, the plurality of first scan lines, the plurality of emission lines, and the plurality of data lines may be included in the circuit layer 510.

In one or more embodiments of the disclosure, each of the plurality of light-emitting pixels 311 may be electrically connected to corresponding ones of the plurality of first scan lines, the plurality of emission lines, and the plurality of data lines. In one or more embodiments of the disclosure, the connection relationship between each of the plurality of light-emitting pixels 311 and the plurality of first scan lines, the plurality of light-emitting lines, and the plurality of data lines may be modified in accordance with the configuration of the light-emitting pixel driving circuit included in each of the plurality of light-emitting pixels 311.

In one or more embodiments of the disclosure, the controller 301 may obtain an image signal and a scan control signal from an external source. The controller 301 may provide the data driver 302 with an output image signal resulting from converting the data format of the obtained image signal to be suitable for the data driver 302 and the display device 110.

In one or more embodiments of the disclosure, the data driver 302 may convert the output image signal into a plurality of data signals and provide the plurality of data signals to the plurality of data lines, respectively. The plurality of data signals may be analog voltages converted to correspond to gray levels of the output image signal.

In one or more embodiments of the disclosure, the scan control signal may include a vertical start signal for initiating an operation of the scan driver 304, a vertical start signal for initiating an operation of the emission driver 305, a clock signal for determining output timings of the vertical start signals, and the like.

In one or more embodiments of the disclosure, the scan driver 304 may generate a plurality of first scan signals based on the scan control signal. The scan driver 304 may provide the plurality of first scan signals to the plurality of first scan lines, respectively.

In one or more embodiments of the disclosure, the emission driver 305 may generate a plurality of emission signals based on the scan control signal. The emission driver 305 may provide the plurality of emission signals to the plurality of emission lines, respectively.

In one or more embodiments of the disclosure, the electronic device 100 may display the output image 111 through the display device 110 by controlling timings for respectively applying the first scan signals, the data signals, and the emission signals to the plurality of light-emitting pixels 311, and adjusting a length or a magnitude of a signal interval included in each signal.

In one or more embodiments of the disclosure, the plurality of light-receiving pixels 320 may be arranged to correspond to the plurality of light-emitting pixels 311, respectively. In detail, when a region including each light-emitting pixel is referred to as a pixel area 310, each light-receiving pixel may be arranged to correspond to the pixel area 310. However, the disclosure is not limited thereto, and it is obvious that two or more light-receiving pixels may be arranged to be included in each pixel area 310.

In one or more embodiments of the disclosure, one light-receiving pixel may be arranged to correspond to each pixel area 310. One light-receiving pixel may be arranged to be included in each pixel area 310. However, the disclosure is not limited thereto, and it is obvious that two or more light-receiving pixels may be arranged to correspond to or be included in each pixel area 310, or one light-receiving pixel may be arranged to correspond to or be included in two or more pixel areas 310.

In one or more embodiments of the disclosure, each of the plurality of light-receiving pixels 320 may include a photodiode configured to sense light provided from an external source and convert the light into an electrical signal. Each of the plurality of light-receiving pixels 320 may sense light reflected from the environment surrounding the display device 110 or light provided from an external source, to obtain an electrical signal corresponding to the surrounding environment.

In one or more embodiments of the disclosure, the plurality of lenses 330 may be arranged to correspond to the light-receiving pixels, respectively. In detail, one lens may be arranged to correspond to one light-receiving pixel.

Although not illustrated in FIG. 3, each of the plurality of light-receiving pixels 320 may be electrically connected to at least one transistor. The at least one transistor electrically connected to each of the plurality of light-receiving pixels 320 may be referred to as a light-receiving pixel driving circuit.

In one or more embodiments of the disclosure, the light-receiving pixel driving circuit may be included in the circuit layer 510 included in the display device 110. The light-receiving pixel driving circuit may be formed through the same process as the light-emitting pixel driving circuit and included in the circuit layer 510.

In one or more embodiments of the disclosure, the plurality of light-receiving pixels 320 included in the pixel layer 540 may be electrically connected to the light-receiving pixel driving circuits included in the circuit layer 510, respectively.

In one or more embodiments of the disclosure, the display device 110 may include a plurality of second scan lines extending from the scan driver 304 in the second direction 20 and arranged to be spaced apart from each other in the first direction 10 intersecting the second direction 20.

In one or more embodiments of the disclosure, the display device 110 may include a plurality of sensing lines extending from the sensing driver 303 in a direction opposite to the first direction 10 and arranged to be spaced apart from each other in the second direction 20.

In one or more embodiments of the disclosure, the plurality of second scan lines and the plurality of sensing lines may be included in the circuit layer 510.

In one or more embodiments of the disclosure, each of the plurality of light-receiving pixels 320 may be electrically connected to corresponding ones of the plurality of second scan lines and the plurality of sensing lines. In one or more embodiments of the disclosure, the connection relationship between each of the plurality of light-receiving pixels 320 and the plurality of second scan lines and the plurality of sensing lines may be modified in accordance with the configuration of the light-receiving pixel driving circuit included in each of the plurality of light-receiving pixels 320.

In one or more embodiments of the disclosure, the scan driver 304 may generate a plurality of second scan signals based on the scan control signal. The scan driver 304 may provide the plurality of second scan signals to the plurality of second scan lines, respectively.

In one or more embodiments of the disclosure, the electronic device 100 may obtain the image data sets 211 and 212 for generating the sensing image 220 through the display device 110 by controlling timings for respectively applying the second scan signals to the plurality of light-receiving pixels 320, and adjusting lengths or magnitudes of signal intervals included in the second scan signals.

In one or more embodiments of the disclosure, the sensing driver 303 may obtain electrical signals sensed from the plurality of light-receiving pixels 320 through a plurality of sensing signals. The sensing driver 303 may obtain the image data sets 211 and 212 by converting the obtained electrical signals.

In one or more embodiments of the disclosure, the electronic device 100 may obtain the first image data set 211 through first-group light-receiving pixels 321 among the plurality of light-receiving pixels 320. Simultaneously, the electronic device 100 may obtain the second image data set 212 through second-group light-receiving pixels 322 among the plurality of light-receiving pixels 320. The first image data set 211 and the second image data set 212 may respectively correspond to image data sets captured under different sensitivity conditions (e.g., a high-sensitivity condition for low-illuminance sensing and a low-sensitivity condition for medium/high-illuminance sensing). The electronic device 100 may obtain the first image data set 211 and the second image data set 212 corresponding to the same scene under different sensitivity conditions by simultaneously applying different driving voltages to the first-group light-receiving pixels 321 and the second-group light-receiving pixels 322.

The electronic device 100 may generate the sensing image 220 based on the first image data set 211 and the second image data set 212. Through the plurality of light-receiving pixels 320 to which a plurality of different driving voltages are applied, the electronic device 100 may obtain the sensing image 220 in which a bright region and a dark region are simultaneously represented with high precision. The electronic device 100 may obtain the sensing image 220 free of ghosting artifacts even for a moving subject.

In one or more embodiments of the disclosure, the display device 110 may include one or more voltage lines for applying driving voltages to the plurality of light-receiving pixels 320, respectively. For example, the display device 110 may include a first voltage line for applying a first driving voltage to the first-group light-receiving pixels 321 and a second voltage line for applying a second driving voltage to the second-group light-receiving pixels 322. However, one or more embodiments of the disclosure is not limited thereto, and the display device 110 may control a connection relationship between the light-receiving pixels 320 and the one or more voltage lines through a separate voltage control circuit. A detailed description of the connection relationship between the plurality of light-receiving pixels 320 and the one or more voltage lines will be described below.

In one or more embodiments of the disclosure, the sensing driver 303 may provide the first image data set and the second image data set to the controller 301, and the controller 301 may obtain (e.g., generate) the sensing image 220 by using the first image data set and the second image data set.

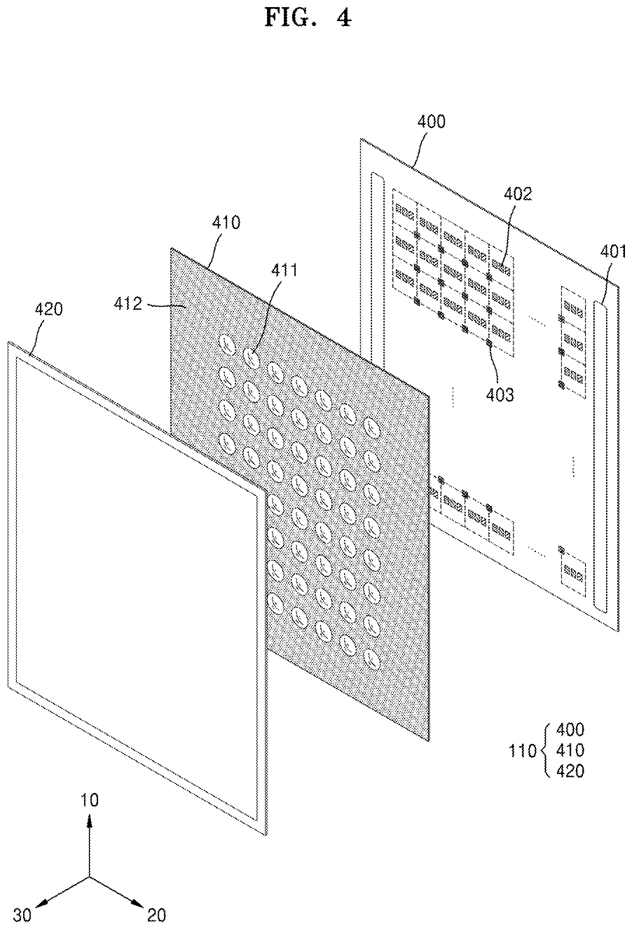

FIG. 4 is a diagram for describing a configuration of a display device according to one or more embodiments of the disclosure.

Referring to FIGS. 1, 3, and 4, in one or more embodiments of the disclosure, the display device 110 included in the electronic device 100 is illustrated in FIG. 4.

In one or more embodiments of the disclosure, the display device 110 may include a display module 400, a lens layer 410, and a window 420. In this case, the display module 400 may include the base layer 500, the circuit layer 510, the pixel layer 540, an optical adhesive layer 550, and the optical layer 560 that are illustrated in FIG. 5. Although FIG. 4 illustrates that the display module 400 includes a driving circuit 401, a plurality of light-emitting pixels 402, and a plurality of light-receiving pixels 403, it is obvious that more components than those illustrated may be included.

In one or more embodiments of the disclosure, the lens layer 410 may include a plurality of lenses 411 and a light-blocking layer 412 surrounding the plurality of lenses 411. In this case, the light-blocking layer 412 may include a plurality of apertures overlapping with the plurality of lenses 411, respectively.

In one or more embodiments of the disclosure, the window 420 may include a transparent material that transmits a first image 111 displayed by the display device 110 or provides light from an external source to the display device 110. For example, the window 420 may include glass, sapphire, plastic, or the like. Although the window 420 is illustrated as a single layer, it is not limited thereto and may include a plurality of layers.

In one or more embodiments of the disclosure, the lens layer 410 may be stacked on the display module 400. Here, ‘on the display module 400’ may mean that the lens layer 410 is stacked on an upper surface of the display module 400 with respect to the third direction 30.

In one or more embodiments of the disclosure, the window 420 may be stacked on the lens layer 410. Here, ‘on the lens layer 410’ may mean that the window 420 is stacked on an upper surface of the lens layer 410 with respect to the third direction 30.

FIG. 5 is a diagram for describing an arrangement of a plurality of components included in a display device, according to one or more embodiments of the disclosure.

Referring to FIGS. 3, 4, and 5, in one or more embodiments of the disclosure, a plurality of components included in the display device 110 are illustrated in FIG. 5.

In one or more embodiments of the disclosure, the display device 110 may include the base layer 500.

In one or more embodiments of the disclosure, the base layer 500 may include a synthetic resin layer. The synthetic resin layer may include a thermosetting resin. In particular, the synthetic resin layer may be a polyimide-based resin layer, and its material is not particularly limited. The synthetic resin layer may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin. In addition, the base layer 500 may include a glass substrate, a metal substrate, an organic/inorganic composite material substrate, or the like.

In one or more embodiments of the disclosure, the display device 110 may include the circuit layer 510 arranged on the base layer 500. In this case, the circuit layer 510 may include circuit elements such as a plurality of transistors 511 for driving a plurality of light-emitting pixels 531 and a plurality of light-receiving pixels 521.

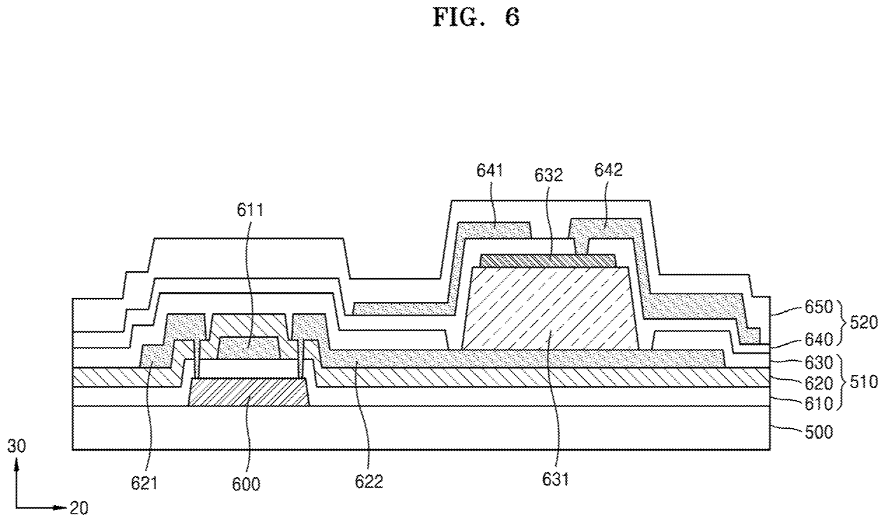

In one or more embodiments of the disclosure, the circuit layer 510 may be arranged on an upper surface of the base layer 500. The circuit layer 510 may be stacked on the base layer 500 in the third direction 30. The circuit layer 510 will be described below with reference to FIG. 6.

In one or more embodiments of the disclosure, the display device 110 may include the pixel layer 540 arranged on the circuit layer 510. The pixel layer 540 may be arranged on an upper surface of the circuit layer 510. The pixel layer 540 may be stacked on the circuit layer 510 in the third direction 30.

In one or more embodiments of the disclosure, the pixel layer 540 may include a light-emitting layer 530 including the plurality of light-emitting pixels 311 and a light-receiving layer 520 including the plurality of light-receiving pixels 521. In one or more embodiments of the disclosure, the light-receiving layer 520 may be arranged on the upper surface of the circuit layer 510, and the light-emitting layer 530 may be arranged on an upper surface of the light-receiving layer 520.

However, the stacking order and the arrangement relationship of the light-emitting layer 530 and the light-receiving layer 520 may vary depending on the types of the plurality of light-emitting pixels 531 and the types of the plurality of light-receiving pixels 521. In one or more embodiments of the disclosure, in a case where the plurality of light-receiving pixels 521 include inorganic photodiodes and the plurality of light-emitting pixels 531 include organic light-emitting diodes, the light-emitting layer 530 may be arranged on the upper surface of the light-receiving layer 520.

On the other hand, in a case where the plurality of light-receiving pixels 521 include inorganic photodiodes and the plurality of light-emitting pixels 531 include inorganic light-emitting diodes, the light-emitting layer 530 and the light-receiving layer 520 may be arranged in the same layer. That is, the plurality of light-receiving pixels 521 and the plurality of light-emitting pixels 531 may be included in the same layer.

In addition, it is obvious that, even in a case where the plurality of light-receiving pixels 521 include organic photodiodes and the plurality of light-emitting pixels 531 include organic light-emitting diodes, the plurality of light-receiving pixels 521 and the plurality of light-emitting pixels 531 may be included on the same layer.

For convenience of description, the following description will assume that the light-emitting pixels 531 include organic light-emitting diodes and the light-receiving pixels 521 include inorganic photodiodes.

In one or more embodiments of the disclosure, each light-receiving pixel may include an active layer 522 for sensing light and converting the light into an electrical signal, and an electrode 523 for applying a voltage to the active layer. In one or more embodiments of the disclosure, in a case where the light-receiving pixel is a PIN diode, the active layer 522 may refer to a PIN layer. However, the disclosure is not limited thereto, and it is obvious that the structure and arrangement of each light-receiving pixel included in the light-receiving layer 520 may vary depending on the type of a photodiode included in the light-receiving pixel.

In one or more embodiments of the disclosure, the light-emitting layer 530 may include the plurality of light-emitting pixels 531 and a protective layer 532 that covers the plurality of light-emitting pixels 531.

In one or more embodiments of the disclosure, the protective layer 532 may be a layer for protecting the plurality of light-emitting pixels 531 from an external environment. The protective layer 532 may refer to a thin-film encapsulation (TFE) layer. Although the protective layer 532 is illustrated as a single layer, the protective layer 532 may have a structure in which a plurality of inorganic layers and organic layers are alternately stacked. In this case, the inorganic layers may protect the plurality of light-emitting pixels 531 from external moisture, and the organic layers may prevent defects in the plurality of light-emitting pixels 531 caused by foreign matter introduced during a manufacturing process. In this case, the protective layer 532 may also be referred to as an encapsulation layer.

However, the disclosure is not limited thereto, and in a case where the plurality of light-emitting pixels 531 include inorganic light-emitting diodes, the protective layer 532 may stabilize surface states, suppress leakage current, or provide an insulation function. In this case, the protective layer 532 may also be referred to as a passivation layer.

In addition, the protective layer 532 may provide a planar surface when the optical layer 560 or the like is coupled onto the pixel layer 540.

In one or more embodiments of the disclosure, the display device 110 may include the optical adhesive layer 550 on the pixel layer 540. The optical adhesive layer 550 may be a layer that serves to couple the pixel layer 540 to the optical layer 560. The optical adhesive layer 550 may be arranged between the pixel layer 540 and the optical layer 560.

However, the optical adhesive layer 550 in FIG. 5 is illustrated for illustrative purposes, and the thickness of the optical adhesive layer 550 included in the display device 110 may be less than that illustrated in FIG. 5. In addition, it is obvious that the configuration of the optical adhesive layer 550 may be omitted in describing the configuration of the display device 110.

In one or more embodiments of the disclosure, the optical adhesive layer 550 is a layer having excellent light transmission characteristics and capable of minimizing optical loss between a plurality of bonded layers and minimizing reflection or refraction of light.

In one or more embodiments of the disclosure, the optical adhesive layer 550 may be a layer formed by applying an optically clear resin (OCR) in a liquid state and then curing it. In addition, the optical adhesive layer 550 may be a layer formed of an optically clear adhesive (OCA) in a film form.

However, the disclosure is not limited thereto, and it is obvious that the optical adhesive layer 550 may include other types of materials having excellent light transmission characteristics and adhesive strength.

In one or more embodiments of the disclosure, the display device 110 may include the optical layer 560 arranged above the pixel layer 540. The optical layer 560 may be stacked on the pixel layer 540 in the third direction 30. In one or more embodiments of the disclosure, the optical layer 560 may be coupled to the pixel layer 540 by using the optical adhesive layer 550.

In one or more embodiments of the disclosure, the optical layer 560 may include an optically transparent material, for example, glass or polyimide (PI).

In one or more embodiments of the disclosure, a thickness 561 of the optical layer 560 may be determined to correspond to the focal length of each of the plurality of lenses. In the disclosure, that the thickness of the optical layer 560 corresponds to the focal length of each of the lenses may mean that the thickness of the optical layer 560 is set such that light passing through each lens is focused on the corresponding light-receiving pixel 521. As the optical layer 560 having a thickness corresponding to the focal length of each lens is arranged between the lens layer 570 and the pixel layer 540, a focal plane of light passing through the lenses coincides with the active area of the corresponding light-receiving pixel 521, such that focused light may reach the corresponding light-receiving pixel 521. Through this, the energy of incident light may enter the corresponding light-receiving pixel 521 with minimum loss, such that the signal-to-noise ratio (SNR) is improved, noise is reduced, and a signal having high sensitivity may be obtained. Accordingly, the light-receiving pixel 521 may obtain information with further improved reliability.

In one or more embodiments of the disclosure, as the optical layer 560 is included in the display device 110, light reflected from an object 590 located at a certain distance from the display device 110 is focused on the plurality of light-receiving pixels 521 through a plurality of lens layers 570, such that the display device 110 may obtain the sensing image 220.

Accordingly, the electronic device 100 may obtain a sensing image 220 by photographing not only an object (e.g., a part of a human body such as a finger) in contact with a surface (e.g., the window 420) of the display device 110, but also an object (e.g., the face or pupils of the user 200 viewing the output image 111 displayed through the display device 110) located at a certain distance from the display device 110.

In one or more embodiments of the disclosure, a protective layer 580 for protecting the plurality of lenses included in the lens layer 570 from an external environment may be arranged on the lens layer 570. Here, although the protective layer 580 is illustrated as a single layer, the protective layer 580 may have a structure in which a plurality of inorganic layers and organic layers are alternately stacked. However, the disclosure is not limited thereto, and the protective layer 580 may refer to the window 420 illustrated in FIG. 4.

FIG. 6 is a diagram for describing a circuit layer and a light-emitting layer, according to one or more embodiments of the disclosure.

Referring to FIGS. 5 and 6, in one or more embodiments of the disclosure, the base layer 500, the circuit layer 510, and the light-receiving layer 520 among a plurality of components included in the display device 110 are illustrated in FIG. 6.

In one or more embodiments of the disclosure, the circuit layer 510 may include a plurality of transistors, and the light-receiving layer 520 may include a plurality of light-receiving pixels. For convenience of description, FIG. 6 illustrates that one transistor and one light-receiving pixel are arranged.

In one or more embodiments of the disclosure, the circuit layer 510 stacked on the base layer 500 may include a first semiconductor pattern 600, a first insulating layer 610, a gate electrode 611, a second insulating layer 620, a source electrode 621, a drain electrode 622, and a third insulating layer 630.

In one or more embodiments of the disclosure, insulating layers included in the circuit layer 510 and the light-receiving layer 520 may include inorganic layers and/or organic layers, and may have a single-layer or multi-layer structure. The insulating layers included in the circuit layer 510 and the light-receiving layer 520 may include at least one of aluminum oxide, titanium oxide, silicon oxide, silicon nitride, silicon oxynitride, zirconium oxide, or hafnium oxide.

In addition, the insulating layers included in the circuit layer 510 and the light-receiving layer 520 may include, but are not limited to, benzocyclobutene (BCB), polyimide, hexamethyldisiloxane (HMDSO), general-purpose polymers such as polymethylmethacrylate (PMMA) or polystyrene (PS), polymer derivatives having a phenol-based group, acrylic-based polymers, imide-based polymers, aryl ether-based polymers, amide-based polymers, fluorine-based polymers, p-xylene-based polymers, vinyl alcohol-based polymers, blends thereof, or the like.

In one or more embodiments of the disclosure, the first semiconductor pattern 600 may be arranged on the base layer 500. In one or more embodiments of the disclosure, the first semiconductor pattern 600 may be divided into a source region, a gate region, and a drain region according to the doping concentration or conductivity of the semiconductor pattern. In one or more embodiments of the disclosure, the source region and the drain region may each be a p-type semiconductor layer or an n-type semiconductor layer. The gate region may be an active layer or a channel layer arranged between the source region and the drain region.

In one or more embodiments of the disclosure, the first semiconductor pattern 600 may include a silicon semiconductor. For example, the silicon semiconductor may include amorphous silicon, polycrystalline silicon, or the like. Alternatively, the first semiconductor pattern 600 may include an oxide of a material selected from Group 12, 13, or 14 metals, such as indium (In), gallium (Ga), tin (Sn), cadmium (Cd), aluminum (Al), germanium (Ge), zinc (Zn), or hafnium (Hf), and combinations thereof.

In one or more embodiments of the disclosure, the first insulating layer 610 may be arranged on the base layer 500. The first insulating layer 610 may cover the first semiconductor pattern 600.

In one or more embodiments of the disclosure, the first insulating layer 610 may be an inorganic layer and/or an organic layer, and may have a single-layer or multi-layer structure.

In one or more embodiments of the disclosure, the gate electrode 611 may be arranged on the first insulating layer 610. The gate electrode 611 may be arranged above the first semiconductor pattern 600. The gate electrode 611 may overlap with the gate region of the first semiconductor pattern 600.

In one or more embodiments of the disclosure, the gate electrode 611 may include, but is not limited to, titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), or the like.

In one or more embodiments of the disclosure, the second insulating layer 620 may be arranged on the first insulating layer 610. The second insulating layer 620 may cover the gate electrode 611. The second insulating layer 620 may have a single-layer or multi-layer structure. The second insulating layer 620 may be an inorganic layer and/or an organic layer.

In one or more embodiments of the disclosure, the source electrode 621 and the drain electrode 622 may be arranged on the second insulating layer 620. The source electrode 621 and the drain electrode 622 may each include, but are not limited to, titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), or the like.

In one or more embodiments of the disclosure, the source electrode 621 may be electrically connected to the source region of the first semiconductor pattern 600 through a through-hole that extends through the first insulating layer 610 and the second insulating layer 620. However, the disclosure is not limited thereto, and the source electrode 621 may be electrically connected to the source region through a connection electrode that extends through the first insulating layer 610 and the second insulating layer 620.

In one or more embodiments of the disclosure, the drain electrode 622 may be electrically connected to the drain region of the first semiconductor pattern 600 through a through-hole that extends through the first insulating layer 610 and the second insulating layer 620. However, the disclosure is not limited thereto, and the drain electrode 622 may be electrically connected to the drain region through a connection electrode that extends through the first insulating layer 610 and the second insulating layer 620.

In one or more embodiments of the disclosure, the third insulating layer 630 may be arranged on the second insulating layer 620. The third insulating layer 630 may cover the source electrode 621 and the drain electrode 622. The third insulating layer 630 may have a single-layer or multi-layer structure. The third insulating layer 630 may be an inorganic layer and/or an organic layer.

The light-receiving layer 520 stacked on the circuit layer 510 may include a second semiconductor pattern 631, a transparent electrode 632, a fourth insulating layer 640, a first electrode 641, a second electrode 642, and a fifth insulating layer 650.

In one or more embodiments of the disclosure, the second semiconductor pattern 631 may be arranged on the drain electrode 622. In one or more embodiments of the disclosure, the second semiconductor pattern 631 may be formed in an opening formed by etching a portion of the third insulating layer 630 that covers the drain electrode 622. The second semiconductor pattern 631 may be electrically connected to the drain electrode 622.

In one or more embodiments of the disclosure, the second semiconductor pattern 631 may include a silicon semiconductor. For example, the silicon semiconductor may include amorphous silicon, polycrystalline silicon, or the like. Alternatively, the second semiconductor pattern 631 may include an oxide of a material selected from Group 12, 13, or 14 metals, such as indium (In), gallium (Ga), tin (Sn), cadmium (Cd), aluminum (Al), germanium (Ge), zinc (Zn), or hafnium (Hf), and combinations thereof.

In one or more embodiments of the disclosure, the second semiconductor pattern 631 may be a PIN layer in which a p-type semiconductor layer, an intrinsic-type (i-type) semiconductor layer, and an n-type semiconductor layer are sequentially stacked. A photocurrent corresponding to light incident on the second semiconductor pattern 631 may be generated and then provided to the drain electrode 622.

In one or more embodiments of the disclosure, the transparent electrode 632 may be arranged on the second semiconductor pattern 631. The transparent electrode 632 may refer to an electrode that is optically transparent and has electrical conductivity. The transparent electrode 632 may include an indium tin oxide (ITO) electrode. However, the disclosure is not limited thereto, and the transparent electrode 632 may include a transparent conductive oxide such as indium zinc oxide (IZO) or gallium-doped zinc oxide (GZO).

In one or more embodiments of the disclosure, the fourth insulating layer 640 may be arranged on the transparent electrode 632. The fourth insulating layer 640 may cover the second semiconductor pattern 631 and the transparent electrode 632. The fourth insulating layer 640 may have a single-layer or multi-layer structure. The fourth insulating layer 640 may be an inorganic layer and/or an organic layer.

In one or more embodiments of the disclosure, the first electrode 641 and the second electrode 642 may be arranged on the fourth insulating layer 640. The first electrode 641 and the second electrode 642 may each include, but are not limited to, titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), or the like.

In one or more embodiments of the disclosure, the second electrode 642 may be electrically connected to the transparent electrode 632 through a through-hole that extends through the fourth insulating layer 640. However, the disclosure is not limited thereto, and the second electrode 642 may be electrically connected to the transparent electrode 632 through a connection electrode that extends through the fourth insulating layer 640.

In one or more embodiments of the disclosure, the first electrode 641 may be an electrode constituting another light-receiving element included in the light-receiving layer 520 or another light-emitting element included in the light-emitting layer 530.

In one or more embodiments of the disclosure, the fifth insulating layer 650 may be arranged on the fourth insulating layer 640. The fifth insulating layer 650 may cover the first electrode 641 and the second electrode 642. The fifth insulating layer 650 may have a single-layer or multi-layer structure. The fifth insulating layer 650 may be an inorganic layer and/or an organic layer.

In one or more embodiments of the disclosure, FIG. 6 is an example of a cross-sectional view for describing a positional relationship among the base layer 500, the circuit layer 510, and the light-receiving layer 520, and it is obvious that the cross-sectional view of each layer may vary depending on the configuration of the driving circuit included in the circuit layer 510 or the type of the light-receiving pixel included in the light-receiving layer 520.

In addition, it is obvious that the light-emitting layer 530 may be arranged on the light-receiving layer 520. A plurality of light-emitting pixels 531 included in the light-emitting layer 530 and a plurality of electrodes for driving the plurality of light-emitting pixels 531 may be arranged on the light-receiving layer 520.

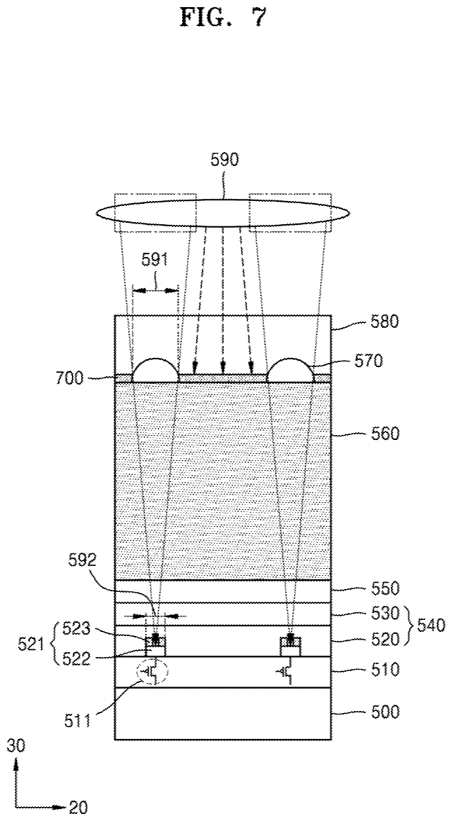

FIG. 7 is a diagram for describing an arrangement of a plurality of components included in a display device, according to one or more embodiments of the disclosure. Hereinafter, the same reference numerals are assigned to the same components as those described above with reference to FIG. 5, and redundant descriptions will be omitted.

Referring to FIGS. 5 and 7, in one or more embodiments of the disclosure, the display device 110 may include the base layer 500, the circuit layer 510, the pixel layer 540, the optical adhesive layer 550, the optical layer 560, the lens layer 570, and the protective layer 580 that are sequentially stacked in the third direction 30.

In one or more embodiments of the disclosure, the circuit layer 510 may include a plurality of transistors 511 for driving a plurality of light-receiving pixels 521 and a plurality of light-emitting pixels included in the pixel layer 540.

In one or more embodiments of the disclosure, the pixel layer 540 may include the light-receiving layer 520 and the light-emitting layer 530. Here, for convenience of description, FIG. 7 illustrates two light-receiving pixels among the plurality of light-receiving pixels 521 included in the light-receiving layer 520, while the plurality of light-emitting pixels included in the light-emitting layer 530 are not illustrated. However, FIG. 7 is a partial cross-sectional view of the display device 110 for illustrative purposes, and it is obvious that the arrangement of the light-receiving pixels and the light-emitting pixels included in the light-receiving layer 520 and the light-emitting layer 530 may be modified.

In addition, in one or more embodiments of the disclosure, the display device 110 may include a light-blocking layer 700 arranged on the optical layer 560. The light-blocking layer 700 may be stacked on the optical layer 560 in the third direction 30. The light-blocking layer 700 may be arranged at an upper end of the optical layer 560. Here, the upper end of the optical layer 560 may refer to a surface that is closer to the object 590 in the third direction 30 as compared to a lower end of the optical layer 560.

In one or more embodiments of the disclosure, the light-blocking layer 700 may include a plurality of first apertures overlapping with a plurality of lenses included in the lens layer 570. In one or more embodiments of the disclosure, each first aperture may overlap with a corresponding lens. In one or more embodiments of the disclosure, the first aperture and the lens corresponding to the first aperture may overlap with each other in the third direction 30.

In one or more embodiments of the disclosure, the light-receiving pixel corresponding to the lens and the first aperture may overlap with each other in the third direction 30. The light-receiving pixel and a non-aperture area of the light-blocking layer 700 may not overlap with each other in the third direction 30.

However, although not illustrated in FIG. 7, the disclosure is not limited thereto, and the light-blocking layer 700 may further include a plurality of apertures overlapping with the plurality of light-emitting pixels included in the pixel layer 540. Through this, light provided through the plurality of light-emitting pixels may be provided as the output image 111 without being blocked by the light-blocking layer 700. Hereinafter, the light-blocking layer included in the display device 110 of the disclosure may include a plurality of apertures overlapping with the plurality of light-emitting pixels.

In one or more embodiments of the disclosure, a width 591 of each of the plurality of first apertures may be equal to a width of each lens. Here, the width of the lens may refer to a diameter of the lens. However, the disclosure is not limited thereto, and the width 591 of each aperture may be less than a diameter of each corresponding lens.

In one or more embodiments of the disclosure, the width of each of the plurality of light-receiving pixels 521 may be referred to as a pixel width 592. The width 591 may be greater than the pixel width 592.

The light-blocking layer described in one or more embodiments of the disclosure may include an optically opaque material. In one or more embodiments of the disclosure, the light-blocking layer may include a metal such as chromium (Cr), molybdenum (Mo), or aluminum (Al), or a resin containing carbon black. However, the disclosure is not limited thereto, and the light-blocking layer may include an inorganic material or an organic material having absorptive or reflective properties.

In one or more embodiments of the disclosure, the light-blocking layer may be patterned through a photolithography process to block external light in an area other than a particular aperture. In one or more embodiments of the disclosure, the light-blocking layer may also be referred to as a black matrix (BM).

In one or more embodiments of the disclosure, the light-blocking layer 700 may prevent light that does not pass through the plurality of lenses from reaching the plurality of light-receiving pixels 521. In detail, light provided to the display device 110 from an external source and passing through each lens may reach the light-receiving pixel corresponding to the lens via the optical layer 560. The light-blocking layer 700 may prevent light that does not pass through each lens from reaching the light-receiving pixel via the optical layer 560.

Through this, when the display device 110 obtains the sensing image 220, it is possible to prevent image quality degradation such as crosstalk, which may occur when noise light that has not passed through the lenses is provided to the light-receiving pixels.

In one or more embodiments of the disclosure, the light-blocking layer may be arranged on the optical adhesive layer 550. Alternatively, in one or more embodiments of the disclosure, a plurality of light-blocking layers may be provided, such that some of the light-blocking layers are arranged on the optical layer 560 while the rest are arranged on the optical adhesive layer 550. Alternatively, in one or more embodiments of the disclosure, some of the plurality of light-blocking layers may be arranged inside the optical layer 560.

Alternatively, in one or more embodiments of the disclosure, the circuit layer 510 may further include a plurality of metal wirings, wherein the metal wirings may be electrodes constituting circuit elements included in the circuit layer 510, may be wirings electrically connected to the circuit elements, or may be components formed by the same process as the electrodes or the wirings. The metal wirings may be designed not to overlap with the light-receiving pixels 521 in a third direction 30, and the metal wirings may prevent noise light from reaching the light-receiving pixels 521. For example, openings may be formed in the metal wirings to overlap with the light-receiving pixels 521 in the third direction 30.

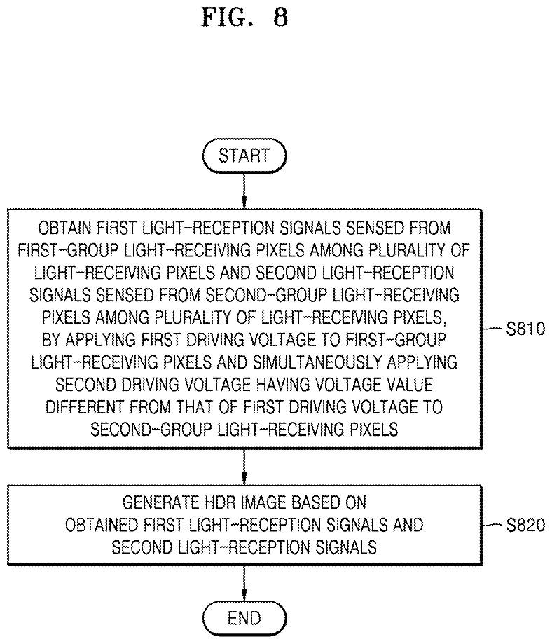

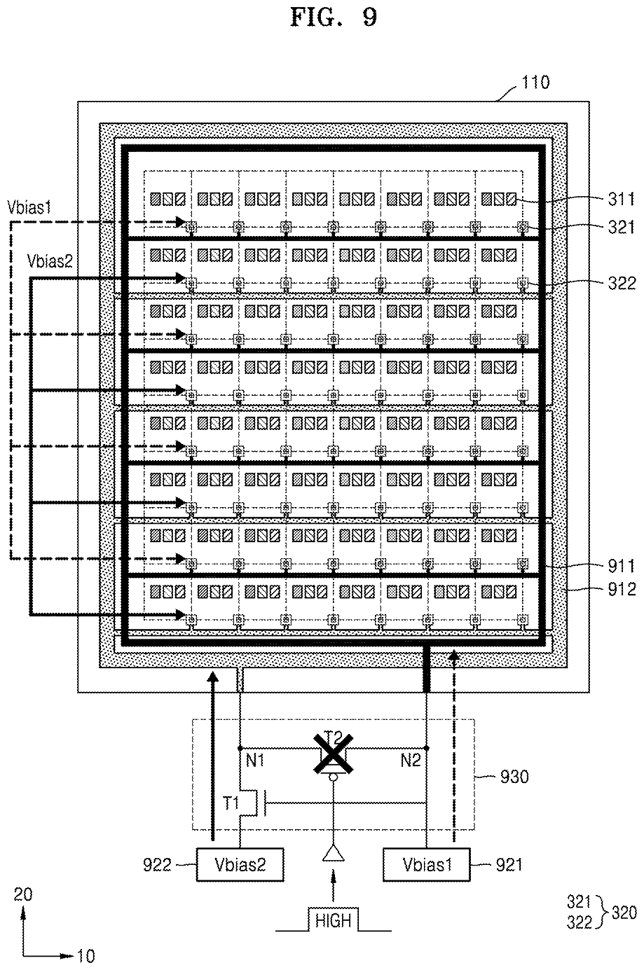

FIG. 8 is a flowchart for describing an operation, performed by an electronic device, of generating an HDR image, according to one or more embodiments of the disclosure. FIG. 9 is a diagram for describing an operation, performed by an electronic device, of obtaining an HDR image, according to one or more embodiments of the disclosure.

Referring to FIG. 8, an operation method of the electronic device 100 according to one or more embodiments of the disclosure may include operations S810 and S820. In one or more embodiments of the disclosure, operations S810 and S820 may be performed by at least one processor 130 included in the electronic device 100. The operation method of the electronic device 100 is not limited to that illustrated in FIG. 8, and in one or more embodiments of the disclosure, the operation method may further include operations that are not illustrated in FIG. 8.

In operation S810 of FIG. 8, the electronic device 100 according to one or more embodiments of the disclosure may obtain first light-reception signals sensed from the first-group light-receiving pixels 321 among the plurality of light-receiving pixels 320 and second light-reception signals sensed from the second-group light-receiving pixels 322 among the plurality of light-receiving pixels 320, by applying a first driving voltage Vbias1 to the first-group light-receiving pixels 321 and applying (e.g., simultaneously applying) a second driving voltage Vbias2 having a voltage value different from that of the first driving voltage Vbias1 to the second-group light-receiving pixels 322.

Referring to FIG. 9 together, in one or more embodiments of the disclosure, the plurality of light-receiving pixels 320 may include the first-group light-receiving pixels 321 and the second-group light-receiving pixels 322. In sensing a surrounding environment at one point in time, the first-group light-receiving pixels 321 may be light-receiving pixels to which the first driving voltage Vbias1 is applied, and the second-group light-receiving pixels 322 may be light-receiving pixels to which the second driving voltage Vbias2 different from the first driving voltage Vbias1 is applied.

In one or more embodiments of the disclosure, the first-group light-receiving pixels 321 and the second-group light-receiving pixels 322 may be alternately arranged in units of rows. Within the same row, the first-group light-receiving pixels 321 may be continuously arranged in the first direction 10 to form a first-group light-receiving pixel row, or the second-group light-receiving pixels 322 may be continuously arranged in the first direction 10 to form a second-group light-receiving pixel row. The first-group light-receiving pixel rows and the second-group light-receiving pixel rows may be alternately arranged in the second direction 20.

However, the arrangement of the first-group light-receiving pixels 321 and the second-group light-receiving pixels 322 is not limited thereto. For example, the first-group light-receiving pixels 321 and the second-group light-receiving pixels 322 may be repeatedly arranged in various forms. Alternatively, for example, some of the first-group light-receiving pixels 321 and the second-group light-receiving pixels 322 may be intensively arranged only in a particular area requiring sensing under a particular sensitivity condition.

In one or more embodiments of the disclosure, the electronic device 100 may include a first voltage supply 921 configured to apply the first driving voltage Vbias1 and a second voltage supply 922 configured to apply the second driving voltage Vbias2. The first driving voltage Vbias1 may be a variable voltage. For example, the first driving voltage Vbias1 may be determined to have a voltage value that enables the first-group light-receiving pixels 321 to detect light under a medium-illuminance condition or a high-illuminance condition. The second driving voltage Vbias2 may be a fixed voltage. For example, the second driving voltage Vbias2 may be determined to have a voltage value that enables the second-group light-receiving pixels 322 to detect light under a low-illuminance condition. The magnitude (or absolute value) of the second driving voltage Vbias2 may be greater than the magnitude (or absolute value) of the first driving voltage Vbias1.

In one or more embodiments of the disclosure, the display device 110 may include a plurality of voltage lines 911 and 912 electrically connected to the plurality of light-receiving pixels 320. For example, the display device 110 may include a first voltage line 911 and a second voltage line 912. The first voltage line 911 may be electrically connected to the first-group light-receiving pixels 321. The second voltage line 912 may be electrically connected to the second-group light-receiving pixels 322. For convenience of description, FIG. 9 exemplarily illustrates only the light-emitting pixels 311, the light-receiving pixels 320, and the voltage lines 911 and 912 electrically connected to the light-receiving pixels 320, among the components of the display device 110.

In one or more embodiments of the disclosure, the electronic device 100 may further include a voltage control circuit 930. The voltage control circuit 930 may be electrically connected to the voltage lines 911 and 912 to control driving voltages applied to the respective voltage lines.

In one or more embodiments of the disclosure, the voltage control circuit 930 may include a first transistor T1 and a second transistor T2. The first transistor T1 may be electrically connected between the second voltage supply 922 and the second voltage line 912. The second transistor T2 may be electrically connected between a first node N1 where the first transistor T1 and the second voltage line 912 are connected to each other, and a second node N2 where the first voltage supply 921 and the first voltage line 911 are connected to each other.

The first transistor T1 may include a gate electrode that receives a gate signal, a first electrode that is connected to the second voltage supply 922 (or receives the second driving voltage Vbias2), and a second electrode that is connected to the second voltage line 912. The first transistor T1 may operate in an on-state based on a gate signal of a first voltage level (e.g., a high level) being applied to the gate electrode. The first transistor T1 may operate in an off-state based on a gate signal of a second voltage level (e.g., a low level) being applied to the gate electrode. For example, the first transistor T1 may be an n-type transistor.

The second transistor T2 may include a gate electrode that receives a gate signal, a first electrode that is connected to the first node N1 where the second electrode of the first transistor T1 and the second voltage line 912 are connected to each other, and a second electrode that is connected to the second node N2 where the first voltage supply 921 and the first voltage line 911 are connected to each other (or receives the first driving voltage Vbias1). The second transistor T2 may operate in an off-state based on a gate signal of the first voltage level (e.g., a high level) being applied to the gate electrode. The second transistor T2 may operate in an on-state based on a gate signal of the second voltage level (e.g., a low level) being applied to the gate electrode. For example, the second transistor T2 may be a p-type transistor.

In one or more embodiments of the disclosure, when a gate signal of the first voltage level (e.g., a high level) is applied to the gate electrode of the first transistor T1 and the gate electrode of the second transistor T2, the first transistor T1 may be turned on and the second transistor T2 may be turned off. As the first transistor T1 is turned on, the second voltage supply 922 and the second voltage line 912 may be electrically connected to each other. As the second transistor T2 is turned off, the first node N1 and the second node N2 may be electrically disconnected from each other. That is, the first voltage supply 921 and the second voltage line 912 may be electrically disconnected from each other. Accordingly, the first driving voltage Vbias1 may be applied to the first voltage line 911 through the first voltage supply 921, and simultaneously, the second driving voltage Vbias2 may be applied to the second voltage line 912 through the second voltage supply 922. The first driving voltage Vbias1 may be applied to the first-group light-receiving pixels 321 through the first voltage line 911, and simultaneously, the second driving voltage Vbias2 may be applied to the second-group light-receiving pixels 322 through the second voltage line 912.

The electronic device 100 may obtain first light-reception signals through the first-group light-receiving pixels 321 to which the first driving voltage Vbias1 is applied. The electronic device 100 may obtain second light-reception signals through the second-group light-receiving pixels 322 to which the second driving voltage Vbias2 is applied. In other words, the electronic device 100 may obtain the first light-reception signals captured under a first sensitivity condition corresponding to the first driving voltage Vbias1, and the second light-reception signals captured under a second sensitivity condition corresponding to the second driving voltage Vbias2. For example, the first sensitivity condition may be a low-sensitivity condition for sensing a medium-illuminance region or a low-sensitivity condition for sensing a high-illuminance region, and the second sensitivity condition may be a high-sensitivity condition for sensing a low-illuminance region.

The configuration of the voltage control circuit 930 is not limited thereto, and any circuit configuration may be employed in which, based on a particular input signal, the first voltage supply 921 may be electrically connected to the first voltage line 911, and the second voltage supply 922 may be electrically connected to the second voltage line 912, simultaneously.

In operation S820 of FIG. 8, the electronic device 100 according to one or more embodiments of the disclosure may generate an HDR image based on the obtained first light-reception signals and second light-reception signals.

Referring to FIG. 9 together, the electronic device 100 may generate a first image data set by digitizing and image-processing the first light-reception signals obtained through the first-group light-receiving pixels 321. The electronic device 100 may generate a second image data set by digitizing and image-processing the second light-reception signals obtained through the second-group light-receiving pixels 322. The first image data set and the second image data set may respectively correspond to image data sets captured under different sensitivity conditions (e.g., a high-sensitivity condition for low-illuminance sensing and a low-sensitivity condition for medium/high-illuminance sensing). That is, the electronic device 100 may obtain the first image data set and the second image data set corresponding to the same scene under different sensitivity conditions by applying (e.g., simultaneously applying) different driving voltages to the first-group light-receiving pixels 321 and the second-group light-receiving pixels 322.

The electronic device 100 may generate the HDR image based on the first image data set and the second image data set. The electronic device 100 may generate the HDR image by registering and fusing the first image data set and the second image data set by using an HDR fusion algorithm. In one or more embodiments of the disclosure, the HDR image may be an image generated based on the first and second image data sets obtained under a low-sensitivity condition for medium/high-illuminance sensing and a high-sensitivity condition for low-illuminance sensing. Accordingly, because the HDR image 220 may represent a brightness range (e.g., a bright region and/or a dark region) that is difficult to represent with an image data set obtained under a single sensitivity condition, the HDR image 220 may provide an extended dynamic range.

According to one or more embodiments of the disclosure, through the plurality of light-receiving pixels 320 to which a plurality of different driving voltages are applied, the electronic device 100 may obtain the sensing image 220 in which a bright region and a dark region are simultaneously represented with high precision. In addition, the electronic device 100 may obtain the sensing image 220 free of ghosting artifacts even for a moving subject.

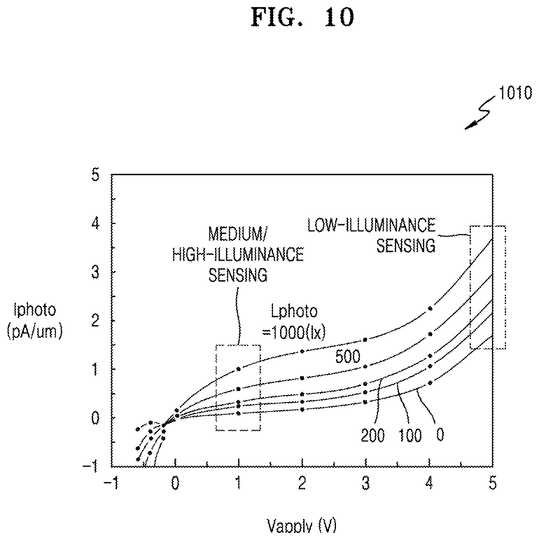

FIG. 10 is a graph showing I-V characteristic curves of a light-receiving pixel, according to one or more embodiments of the disclosure.

A graph 1010 of FIG. 10 shows changes in photocurrent Iphoto according to an applied driving voltage Vapply under different incident light illuminance conditions. In the graph 1010 of FIG. 10, the incident light illuminance conditions were set to 0 lx, 100 lx, 200 lx, 500 lx, and 1000 lx, and the applied driving voltage was set in a range of about −1 V to about 5 V.

As shown in the graph 1010 of FIG. 10, the light-receiving pixel may exhibit variable photosensitivity characteristics in which response characteristics of photocurrent to incident light illuminance vary depending on the applied driving voltage. It may be confirmed that the measured photocurrent tends to increase as the applied driving voltage increases across all illuminance conditions. In addition, it may be confirmed that the measured photocurrent tends to increase as the incident light illuminance increases under a condition where the same driving voltage is applied.

When a high driving voltage (e.g., 3.5 V to 5 V) is applied, the photocurrent increases relatively significantly even in a low-illuminance region (e.g., 0 lx to 100 lx). Accordingly, when a relatively high driving voltage is applied to the light-receiving pixels, sufficient electrical signals are secured even for the low-illuminance region corresponding to a relatively dark area, such that the dark area may be sensed relatively brightly. The electronic device 100 may sense a low-illuminance region under a high-sensitivity condition by applying a high driving voltage, thereby mitigating detail loss in a dark region.

Conversely, when a low driving voltage (e.g., 0 V to 1.5 V) is applied, the increase rate of the photocurrent is limited in a medium/high-illuminance region (e.g., 500 lx to 1000 lx). Accordingly, when a relatively low driving voltage is applied to the light-receiving pixels, the slope of the photocurrent remains gradual even for a medium/high-illuminance region corresponding to a relatively bright area, and thus, relatively low electrical signals are generated, such that the bright area may be sensed relatively darkly. The electronic device 100 may sense a medium/high-illuminance region under a low-sensitivity condition by applying a low driving voltage, thereby preventing signal saturation and mitigating detail loss in a bright region.

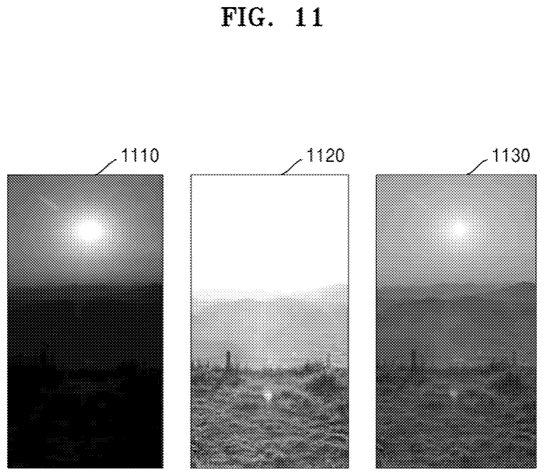

FIG. 11 illustrates examples of images obtained through a plurality of light-receiving pixels, according to one or more embodiments of the disclosure. FIG. 11 illustrates, for the same scene, examples of a first image 1110 captured in a low-illuminance environment, a second image 1120 captured in a high-illuminance environment, and a third image 1130 corresponding to an HDR image.

Referring to FIG. 11, as the first image 1110 is captured in the low-illuminance environment, the amount of light incident on each light-receiving pixel may be relatively small. Because the magnitude of an electrical signal generated in each light-receiving pixel is low, an output difference between adjacent light-receiving pixels may not be sufficiently secured. Accordingly, the first image 1110, in which information in a dark region within the same scene is lost and details of the dark region are not sufficiently reproduced, may be output.

As the second image 1120 is captured in the high-illuminance environment, the amount of light incident on each light-receiving pixel may be relatively large. As an electrical signal generated in each light-receiving pixel approaches or exceeds the maximum operating range, a saturation phenomenon may occur in which the output signal no longer increases even when the illuminance increases. Accordingly, the second image 1120, in which information in a bright region within the same scene is lost and details of the bright region are not sufficiently reproduced, may be output.

The third image 1130 may be an image generated by reflecting data sensed with high sensitivity by applying a high driving voltage to the corresponding light-receiving pixels for a low-illuminance region, and simultaneously reflecting data sensed with low sensitivity by applying a low driving voltage to the corresponding light-receiving pixels for a high-illuminance region. Accordingly, for a low-illuminance region, details of a dark region may be secured by amplifying an output signal, and for a high-illuminance region, details of a bright region may be secured by limiting an excessive increase in the output signal. Therefore, it may be confirmed that, in an HDR image, both a bright region and a dark region may be clearly represented by combining data sets captured under different sensitivity conditions.

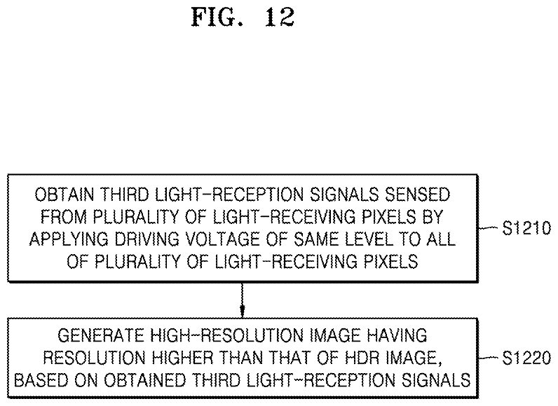

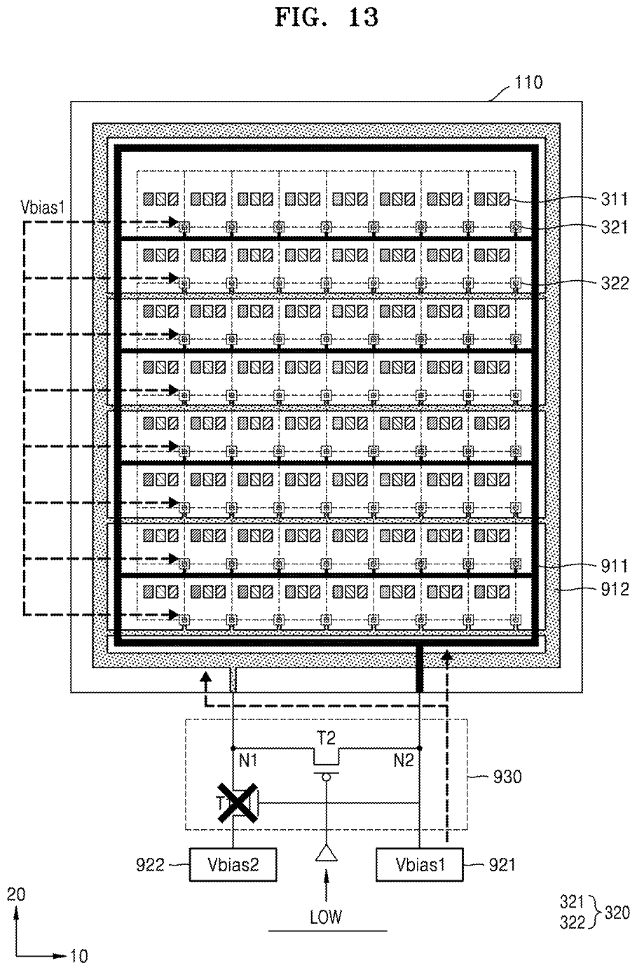

FIG. 12 is a flowchart for describing an operation, performed by an electronic device, of generating a high-resolution image, according to one or more embodiments of the disclosure. FIG. 13 is a diagram for describing an operation, performed by an electronic device, of obtaining a high-resolution image, according to one or more embodiments of the disclosure. In FIG. 13, the same reference numerals are assigned to components corresponding to those described above with reference to FIG. 9, and because the configuration and operations thereof are substantially the same, detailed descriptions thereof will be omitted, while primarily describing the differences.

Referring to FIG. 12, the operation method of the electronic device 100 according to one or more embodiments of the disclosure may further include operations S1210 and S1220. In one or more embodiments of the disclosure, operations S1210 and S1220 may be performed by at least one processor 130 included in the electronic device 100. The operation method of the electronic device 100 is not limited to that illustrated in FIG. 12, and in one or more embodiments of the disclosure, the operation method may further include operations that are not illustrated in FIG. 12.

In operation S1210 of FIG. 12, the electronic device 100 according to one or more embodiments of the disclosure may obtain third light-reception signals sensed from a plurality of light-receiving pixels by applying a driving voltage of the same level to all of the plurality of light-receiving pixels.

Referring to FIG. 13 together, in one or more embodiments of the disclosure, the plurality of light-receiving pixels 320 may include the first-group light-receiving pixels 321 and the second-group light-receiving pixels 322. The first-group light-receiving pixels 321 may be electrically connected to the first voltage line 911. The second-group light-receiving pixels 322 may be electrically connected to the second voltage line 912.

In one or more embodiments of the disclosure, the electronic device 100 may further include the voltage control circuit 930. The voltage control circuit 930 may be electrically connected to the voltage lines 911 and 912 to control driving voltages applied to the respective voltage lines. Because the configuration of the voltage control circuit 930 has been described in detail with reference to FIG. 9, a description thereof will be omitted below.

In one or more embodiments of the disclosure, when a gate signal of a second voltage level (e.g., a low level) is applied to the gate electrode of the first transistor T1 and the gate electrode of the second transistor T2, the first transistor T1 may be turned off and the second transistor T2 may be turned on. As the first transistor T1 is turned off, the second voltage supply 922 and the second voltage line 912 may be electrically disconnected from each other. As the second transistor T2 is turned on, the first node N1 and the second node N2 may be electrically connected to each other. That is, the first voltage supply 921 and the second voltage line 912 may be electrically connected to each other. Accordingly, the first driving voltage Vbias1 may be applied to the first voltage line 911 through the first voltage supply 921, and simultaneously, the first driving voltage Vbias1 may also be applied to the second voltage line 912 through the first voltage supply 921. The first driving voltage Vbias1 may be applied to the first-group light-receiving pixels 321 through the first voltage line 911, and simultaneously, the first driving voltage Vbias1 may also be applied to the second-group light-receiving pixels 322 through the second voltage line 912. That is, the first driving voltage Vbias1 of the same level may be applied to all of the light-receiving pixels 320. The first driving voltage Vbias1 may be a variable voltage. For example, the first driving voltage Vbias1 may be determined to have a voltage value that enables the first-group light-receiving pixels 321 to detect light under any one of a low-illuminance condition, a medium-illuminance condition, or a high-illuminance condition.

The electronic device 100 may obtain third light-reception signals through the light-receiving pixels 320 to which the first driving voltage Vbias1 is applied. The electronic device 100 may obtain the third light-reception signals captured under a sensitivity condition corresponding to the first driving voltage Vbias1. For example, the sensitivity condition corresponding to the first driving voltage Vbias1 may be selected from among a low-illuminance condition, a medium-illuminance condition, and a high-illuminance condition. That is, by applying a driving voltage of the same level to all of the light-receiving pixels 320, the electronic device 100 may obtain light-reception signals captured under the same sensitivity condition from all of the light-receiving pixels 320.

The configuration of the voltage control circuit 930 is not limited thereto, and any circuit configuration may be employed in which, based on a particular input signal, the first voltage supply 921 may be electrically connected to the first voltage line 911 and the second voltage line 912, simultaneously.

In operation S1220 of FIG. 12, the electronic device 100 according to one or more embodiments of the disclosure may generate a high-resolution image having a resolution higher than that of an HDR image, based on the obtained third light-reception signals.

Referring to FIG. 13 together, the electronic device 100 may generate a third image data set by digitizing and image-processing the third light-reception signals obtained through all of the light-receiving pixels 320. The third image data set may correspond to image data sets captured under a particular sensitivity condition (e.g., a low-illuminance, medium-illuminance, or high-illuminance condition). By simultaneously applying driving voltages of the same level to all of the light-receiving pixels 320, the electronic device 100 may obtain the third image data set corresponding to the same scene captured under a particular sensitivity condition.

According to one or more embodiments of the disclosure, through the voltage control circuit 930 configured to control electrical connections between the light-receiving pixels 320 and the voltage supply units 921 and 922, the electronic device 100 may electrically connect all of the light-receiving pixels 320 to the same voltage supply (e.g., the first voltage supply 921). The electronic device 100 may obtain a sensing image represented under a particular sensitivity condition, through all of the light-receiving pixels 320 to which driving voltages of the same level are applied. In the disclosure, the sensing image represented under a particular sensitivity condition through all of the light-receiving pixels 320 may be referred to as a high-resolution image. The high-resolution image may have a resolution higher than that of an HDR image, which is generated based on a first image data set represented under a first sensitivity condition through a portion of the light-receiving pixels 320 (e.g., the first-group light-receiving pixels 321) and a second image data set represented under a second sensitivity condition through another portion of the light-receiving pixels (e.g., the second-group light-receiving pixels 322). The high-resolution image may be generated by capturing the same scene under a particular sensitivity condition through all of the light-receiving pixels 320.

In one or more embodiments of the disclosure, the electronic device 100 may selectively generate the HDR image described above with reference to FIGS. 8 and 9 or the high-resolution image described above with reference to FIGS. 12 and 13 through the voltage control circuit 930 configured to control electrical connections between the light-receiving pixels 320 and the voltage supply units 921 and 922. In the disclosure, performing an operation of obtaining an HDR image by the electronic device may be defined as performing a “first mode,” and performing an operation of obtaining a high-resolution image by the electronic device may be defined as performing a “second mode.”

In one or more embodiments of the disclosure, the electronic device 100 may selectively operate in the first mode or the second mode according to an imaging environment. That is, the electronic device 100 may selectively generate an HDR image or a high-resolution image according to the imaging environment. For example, the electronic device 100 may select an image generation mode based on an illuminance condition of the imaging environment and/or a dynamic range of the scene. When the contrast of the scene is low and sufficient gradation may be secured within a single exposure range, the electronic device 100 may operate in the first mode to generate a high-resolution image. In contrast, when the difference between a bright region and a dark region of the scene is large, the electronic device 100 may operate in the second mode to generate an HDR image having an extended dynamic range, in which the bright region and the dark region are simultaneously represented with high precision. The electronic device 100 may selectively provide the first mode for generating an HDR image and the second mode for generating a high-resolution image, thereby obtaining an image having optimal image quality for the sensing environment. According to one or more embodiments of the disclosure, the electronic device 100 may identify the illuminance condition of the sensing environment and/or the dynamic range of the scene by obtaining light-reception signals in the sensing environment through the light-receiving pixels before selecting the operation mode.

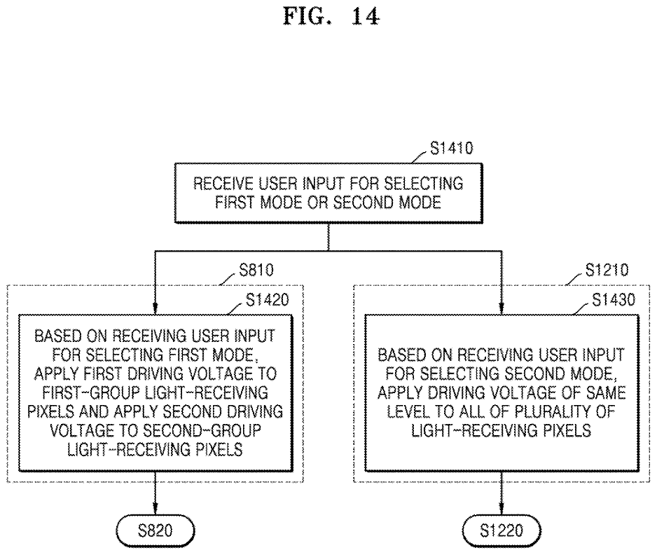

Alternatively, in one or more embodiments of the disclosure, the electronic device 100 may selectively operate in the first mode or the second mode according to a user selection. That is, the electronic device 100 may selectively generate an IDR image or a high-resolution image according to a user selection. This will be described in detail below with reference to FIG. 14.

FIG. 14 is a flowchart for describing an operation, performed by an electronic device, of applying a driving voltage to light-receiving pixels, according to one or more embodiments of the disclosure.

Referring to FIG. 14, the operation method of the electronic device 100 according to one or more embodiments of the disclosure may further include operations S1410 to S1430. In one or more embodiments of the disclosure, operations S1410 to S1430 may be performed by at least one processor 130 included in the electronic device 100. Operation S1420 may be a detailed implementation of operation S810 of FIG. 8. Operation S1430 may be a detailed implementation of operation S1210 of FIG. 12.

In operation S1410 of FIG. 14, the electronic device 100 according to one or more embodiments of the disclosure may receive a user input for selecting the first mode or the second mode. The electronic device 100 may display, through the display device 110, a user interface for selecting a mode of obtaining a sensing image. The electronic device 100 may receive, through the user interface, a user input for selecting a mode of executing a sensing image.

In operation S1420 of FIG. 14, the electronic device 100 according to one or more embodiments of the disclosure may, based on receiving a user input for selecting the first mode, apply a first driving voltage to the first-group light-receiving pixels and apply a second driving voltage to the second-group light-receiving pixels. That is, in operation S1410, based on receiving a user input for selecting the first mode to obtain an HDR image, the electronic device 100 may perform operation S1420. That is, when obtaining a sensing image, the electronic device 100 may perform the first mode. The sensing operation of operation S1420 may be substantially the same as the operation described above with reference to operation S810. Thereafter, the electronic device 100 may perform operation S820 to generate an HDR image based on first light-reception signals obtained from the first-group light-receiving pixels and second light-reception signals obtained from the second-group light-receiving pixels. Because the operation of performing the first mode has been described in detail above with reference to FIGS. 8 and 9, a detailed description thereof will be omitted below.

In operation S1430 of FIG. 14, the electronic device 100 according to one or more embodiments of the disclosure may, based on receiving a user input for selecting the second mode, apply a driving voltage of the same level to all of the plurality of light-receiving pixels. That is, in operation S1410, based on receiving a user input for selecting the second mode to obtain a high-resolution image, the electronic device 100 may perform operation S1430. That is, when obtaining a sensing image, the electronic device 100 may perform the second mode. The sensing operation of operation S1430 may be substantially the same as the operation described above with reference to operation S1210. Thereafter, the electronic device 100 may perform operation S1220 to generate a high-resolution image based on the third light-reception signals obtained from the light-receiving pixels. Because the operation of performing the second mode has been described in detail above with reference to FIGS. 12 and 13, a detailed description thereof will be omitted below.

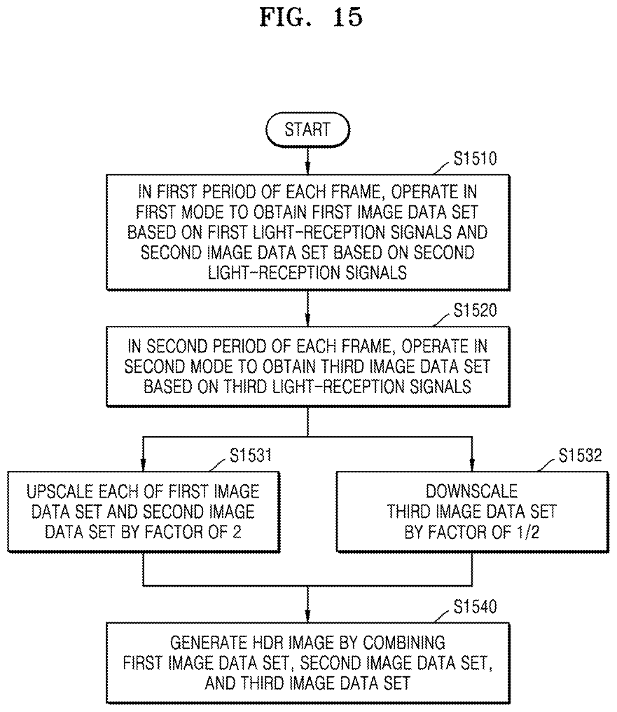

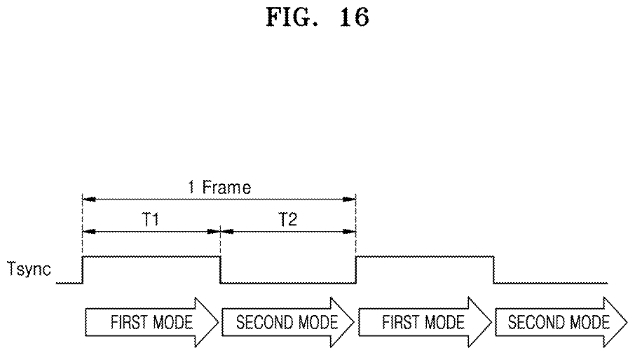

FIG. 15 is a flowchart for describing an operation, performed by an electronic device, of generating an HDR image, according to one or more embodiments of the disclosure. FIG. 16 is a diagram for describing an operation, performed by an electronic device, of obtaining a plurality of light-reception signals through time division of each frame, according to one or more embodiments of the disclosure.

Referring to FIG. 15, the operation method of the electronic device 100 according to one or more embodiments of the disclosure may further include operations S1510 to S1540. In one or more embodiments of the disclosure, operations S1510 to S1540 may be performed by at least one processor 130 included in the electronic device 100.

In one or more embodiments of the disclosure, the electronic device 100 may generate an HDR image by referring to third light-reception signals obtained through the second mode operation, as well as first light-reception signals and second light-reception signals obtained through the first mode operation. This will be described in detail with reference to FIGS. 15 and 16.

In operation S1510 of FIG. 15, the electronic device 100 according to one or more embodiments of the disclosure may, in a first period of each frame, operate in the first mode to obtain a first image data set based on first light-reception signals and a second image data set based on second light-reception signals. In operation S1520 of FIG. 15, the electronic device 100 according to one or more embodiments of the disclosure may, in a second period of each frame, operate in the second mode to obtain a third image data set based on third light-reception signals.

Referring to FIG. 16 together, a one-frame period (1 Frame) may be time-divided into a first-mode sensing period t1 and a second-mode sensing period t2.

During the first-mode sensing period t1, the electronic device 100 may supply a driving signal corresponding to the first mode to the voltage control circuit. For example, the voltage control circuit may correspond to the voltage control circuit 930 illustrated in FIG. 9. Here, as illustrated in FIG. 9, during the first-mode sensing period T1, the electronic device 100 may supply a gate signal of a first voltage level (e.g., a high level) to the gate electrode of the first transistor T1 and the gate electrode of the second transistor T2. Through the voltage control circuit 930, the electronic device 100 may electrically connect the first-group light-receiving pixels 321 to the first voltage supply 921 providing the first driving voltage Vbias1, and electrically connect the second-group light-receiving pixels 322 to the second voltage supply 922 providing the second driving voltage Vbias2.

Through this, during the first-mode sensing period t1, the electronic device 100 may apply the first driving voltage Vbias1 to the first-group light-receiving pixels 321 among the plurality of light-receiving pixels 320 and apply (e.g., simultaneously apply) the second driving voltage Vbias2 having a voltage value different from that of the first driving voltage Vbias1 to the second-group light-receiving pixels 322 among the plurality of light-receiving pixels 320. During the first-mode sensing period t1, the sensing driver may obtain first light-reception signals from the first-group light-receiving pixels 321 and obtain second light-reception signals from the second-group light-receiving pixels 322. The electronic device 100 may generate a first image data set by digitizing and image-processing the first light-reception signals obtained through the first-group light-receiving pixels 321. The electronic device 100 may generate a second image data set by digitizing and image-processing the second light-reception signals obtained through the second-group light-receiving pixels 322. The first image data set and the second image data set may respectively correspond to image data sets captured under different sensitivity conditions (e.g., a high-sensitivity condition for low-illuminance sensing and a low-sensitivity condition for medium/high-illuminance sensing).

During the second-mode sensing period t2, the electronic device 100 may supply a driving signal corresponding to the second mode to the voltage control circuit. For example, the voltage control circuit may correspond to the voltage control circuit 930 illustrated in FIG. 13. Here, as illustrated in FIG. 13, during the second-mode sensing period t2, the electronic device 100 may supply a gate signal of a second voltage level (e.g., a low level) to the gate electrode of the first transistor T1 and the gate electrode of the second transistor T2. Through the voltage control circuit 930, the electronic device 100 may electrically connect the first-group light-receiving pixels 321 to the first voltage supply unit 921 providing the first driving voltage Vbias1, and also electrically connect the second-group light-receiving pixels 322 to the first voltage supply 921 providing the first driving voltage Vbias1. The first driving voltage Vbias1 applied in the second mode may be identical to or different from the first driving voltage Vbias1 applied in the first mode.

Through this, during the second-mode sensing period t2, the electronic device 100 may apply the first driving voltage Vbias1 of the same level to all of the light-receiving pixels 320. During the second-mode sensing period t2, the sensing driver may obtain third light-reception signals from all of the light-receiving pixels 320. The electronic device 100 may generate a third image data set by digitizing and image-processing the third light-reception signals obtained through the light-receiving pixels 320. The third image data set may correspond to image data sets captured under a particular sensitivity condition (e.g., a low-illuminance, medium-illuminance, or high-illuminance condition). The third image data set obtained from all of the light-receiving pixels 320 may have a resolution higher than that of each of the first and second image data sets obtained from some of the light-receiving pixels.

In one or more embodiments of the disclosure, the controller 301 (see FIG. 3) may generate a synchronization signal Tsync for synchronizing operation timings of the first mode and the second mode. The first-mode sensing period t1 and the second-mode sensing period t2 may be alternately switched by changing the synchronization signal Tsync at predetermined time intervals. For example, in response to the synchronization signal Tsync at a high-level voltage, the display device 110 may, during the first-mode sensing period t1, apply the first driving voltage Vbias1 to the first-group light-receiving pixels 321 and simultaneously apply the second driving voltage Vbias2 to the second-group light-receiving pixels 322. In response to the synchronization signal Tsync at a low-level voltage, during the second-mode sensing period t2, the display device 110 may apply the first driving voltage Vbias1 to all of the light-receiving pixels 320.

In one or more embodiments of the disclosure, after performing operation S1520 of FIG. 15, the electronic device 100 may perform operation S1531 of FIG. 15. In operation S1531 of FIG. 15, the electronic device 100 may upscale each of the first image data set and the second image data set by a factor of 2. Through this, the resolution of each of the first image data set and the second image data set may be matched with the resolution of the third image data set.

For example, the electronic device 100 may expand the resolution of the first image data set by a factor of 2 in each of the horizontal and vertical directions, thereby increasing the total number of pixels by a factor of 4. The electronic device 100 may expand the resolution of the second image data set by a factor of 2 in each of the horizontal and vertical directions, thereby increasing the total number of pixels by a factor of 4. To fill in empty spaces of the expanded pixels, the electronic device 100 may use an interpolation algorithm (e.g., nearest-neighbor interpolation or bilinear interpolation) or a neural network-based super-resolution model.

Alternatively, in one or more embodiments of the disclosure, after performing operation S1520 of FIG. 15, the electronic device 100 may perform operation S1532 of FIG. 15. In operation S1532 of FIG. 15, the electronic device 100 may downscale the third image data set by a factor of ½. Through this, the resolution of the third image data set may be matched with the resolution of each of the first image data set and the second image data set.

For example, the electronic device 100 may reduce the resolution of the third image data set by a factor of ½ in each of the horizontal and vertical directions, thereby decreasing the total number of pixels by a factor of ¼. To integrate various image data sets into one, the electronic device 100 may use a filtering method based on a mean, a weighted average, a median, sub-sampling, or an anti-aliasing filter.

The electronic device 100 may convert all of the first to third image data sets into image data sets having the same resolution through operation S1531 of FIG. 15 or operation S1532 of FIG. 15. Thereafter, in operation S1532 of FIG. 15, the electronic device 100 may generate an HDR image by combining the first image data set, the second image data set, and the third image data set.

When operation S1531 of FIG. 15 is performed, the electronic device 100 may combine the third image data set with the upscaled first and second image data sets. Alternatively, when operation S1532 of FIG. 15 is performed, the electronic device 100 may combine the first and second image data sets with the downscaled third image data set.

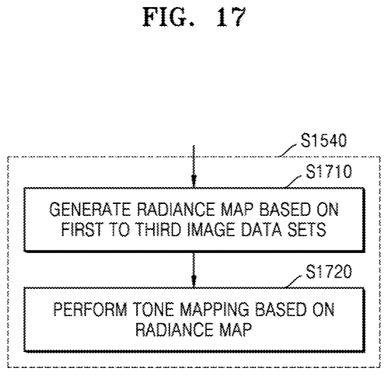

The electronic device 100 may generate an HDR image by registering and fusing the first to third image data sets by using various HDR fusion algorithms. Detailed descriptions of various HDR fusion algorithms will be provided below with reference to FIGS. 17 to 19.

According to one or more embodiments of the disclosure, for a scene to be sensed, the electronic device 100 may simultaneously obtain a plurality of image data sets captured under different sensitivity conditions and a high-resolution image data set captured under a single sensitivity condition. The electronic device 100 may obtain a sensing image represented in an extended dynamic range through the plurality of image data sets obtained under different sensitivity conditions. Furthermore, the electronic device 100 may obtain a high-resolution sensing image through the image data set obtained under a single sensitivity condition. Accordingly, the electronic device 100 may obtain a sensing image in which a bright region and a dark region are simultaneously represented with high precision and high resolution.

Hereinafter, various HDR fusion algorithms will be described in detail with reference to FIGS. 17 to 19.

FIG. 17 is a flowchart for describing an operation, performed by an electronic device, of generating an HDR image based on a plurality of light-reception signals, according to one or more embodiments of the disclosure.

Referring to FIG. 17, the operation method of the electronic device 100 according to one or more embodiments of the disclosure may further include operations S1710 and S1720. In one or more embodiments of the disclosure, operations S1710 and S1720 may be performed by at least one processor 130 included in the electronic device 100. Operations S1710 and S1720 may be detailed implementations of the operation S1540 of FIG. 15.

In operation S1710 of FIG. 17, the electronic device 100 according to one or more embodiments of the disclosure may generate a radiance map based on first to third image data sets. For example, the electronic device 100 may estimate a relative exposure time of each light-receiving pixel based on a sensing condition of the light-receiving pixel. The electronic device 100 may generate a radiance map based on the first to third image data sets and the estimated relative exposure times.

The electronic device 100 may obtain pixel brightness values of the light-receiving pixels according to various value shutter setting (VSS) values. The VSS may be a parameter that indirectly determines pixel brightness and an amount of charge accumulated in the light-receiving pixel by controlling an exposure condition. For example, the VSS may include a driving voltage applied to the light-receiving pixel. The pixel brightness may be a brightness value representing a result of converting an electrical signal generated by the light-receiving pixel receiving light, into a digital value. Based on a plurality of pixel brightness values obtained, the electronic device may generate a regression model in the form of P=G(VSS) by estimating a functional relationship between the VSS value and the pixel brightness P through regression analysis.

Pixel intensity of the light-receiving pixel has a characteristic of increasing in proportion to exposure time. This is because the light-receiving pixel collects a larger amount of light as the exposure time increases. Because the exposure time has a direct correlation with the pixel brightness, the regression model G(VSS) may be equally applied to estimation of the exposure time. Therefore, a regression model in the form of E=G(VSS) may be defined by substituting the correlation equation in the form of P=G(VSS) to correspond to the exposure time E. Through this, the electronic device 100 may estimate, from the set VSS value, an exposure time corresponding to capturing the scene. Here, the electronic device 100 may directly generate a regression model internally, or may receive a regression model generated by an external electronic device.

A radiance map may be data that numerically represents a physical amount of light (radiance) (or an actual amount of light) incident on each light-receiving pixel in a scene to be sensed. The radiance map may be represented as a function of exposure time. A radiance calculation function may be defined as F(E), and a physical amount of light may be calculated by excluding, through the radiance calculation function F(E), exposure time information reflected in a pixel brightness value. By substituting the regression model E=G(VSS) for exposure time into the radiance calculation function F(E), the radiance map may be calculated based on F(G(VSS)). That is, according to one or more embodiments of the disclosure, the electronic device may generate a radiance map by estimating an exposure time from a VSS value and applying the exposure time to the radiance calculation function to derive radiance values of the sensed scene.

In addition, the electronic device 100 may derive first to third radiance values respectively corresponding to first to third image data sets at each pixel (or at the same position). Here, the electronic device 100 may generate a single radiance value by combining the first to third radiance values. For example, the electronic device 100 may determine a single radiance value at the corresponding pixel by weighted-averaging the first to third radiance values according to reliability of pixel brightness. Here, a relatively low weight may be assigned to a high pixel brightness value or a low pixel brightness value, and a relatively high weight may be assigned to a medium pixel brightness value.

In operation S1720 of FIG. 17, the electronic device 100 according to one or more embodiments of the disclosure may perform tone mapping based on the radiance map.

For example, the electronic device 100 may convert the overall brightness distribution into a form suitable for a low dynamic range (LDR) by applying a predefined tone mapping function (or a predefined operation rule) to each pixel of the radiance map to compress relatively high radiance values, and correcting relatively low radiance values. Through this, the electronic device 100 may compress the radiance map into a range representable by a display. Therefore, the electronic device 100 may generate a final sensing image (i.e., an HDR image) by reflecting the radiance values adjusted through the tone mapping.

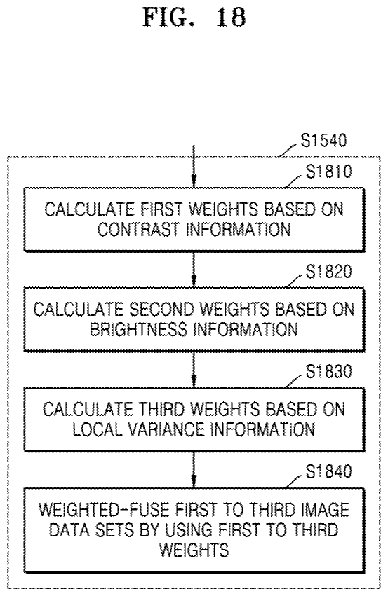

FIG. 18 is a flowchart for describing an operation, performed by an electronic device, of generating an HDR image based on a plurality of light-reception signals, according to one or more embodiments of the disclosure.

Referring to FIG. 18, the operation method of the electronic device 100 according to one or more embodiments of the disclosure may further include operations S1810 to S1840. In one or more embodiments of the disclosure, operations S1810 to S1840 may be performed by at least one processor 130 included in the electronic device 100. Operations S1810 to S1840 may be detailed implementations of the operation S1540 of FIG. 15.

The electronic device 100 according to one or more embodiments of the disclosure may generate an HDR image by weighted-fusing first to third image data sets. Here, the electronic device 100 may generate a weighted fusion map capable of assigning low weights to saturated pixels and dark pixels and assigning weights to regions where details are clearly visible. In the disclosure, a saturated pixel may refer to a pixel in which the pixel brightness value reaches a maximum charge amount such that an additional change in the amount of light is not reflected. In the disclosure, a dark pixel may refer to a pixel in which the pixel brightness value is within a relatively small range due to low illuminance of the scene or an underexposure state of a light-receiving pixel. In the disclosure, a weighted fusion map may be a map including weights assigned based on reliability to image data sets at the same position among a plurality of image data sets obtained under different illuminance conditions.

In operation S1810 of FIG. 18, the electronic device 100 according to one or more embodiments of the disclosure may calculate first weights based on contrast information. The first weights may also be referred to as contrast weights. The contrast may be a value representing a degree of visual differentiation determined by a difference in pixel brightness values between adjacent pixels or between adjacent regions. Because a region having high contrast is highly likely to be a region where details are clearly visible, the electronic device 100 may calculate the first weights for assigning high weights to regions having high contrast. A first weight C may be represented by Equation 1 below.

$${C}_{j} ( x , y ) = \vert Δ {I}_{j} ( x , y ) \vert \qquad [ Equation 1 ]$$

Here, (x, y) may denote a position of a pixel, j may denote a j-th sensed scene, and ΔI may denote a pixel-wise contrast value. For example, the pixel-wise contrast value may be calculated by applying a high-frequency component extraction operation, such as a first-order derivative-based Sobel filter or a second-order derivative-based Laplacian filter, but one or more embodiments of the disclosure is not limited thereto.

In operation S1820 of FIG. 18, an electronic device 100 according to one or more embodiments of the disclosure may calculate second weights based on brightness information. The second weights may also be referred to as brightness weights. Because details are highly likely to be well preserved at medium brightness, the electronic device 100 may calculate the second weights for assigning a higher weight as the pixel brightness value is closer to a medium value. A second weight M may be represented by Equation 2 below.

$${M}_{j} ( x , y ) = exp ( - \frac{{( {I}_{j} ( x , y ) - 0.5 )}^{2}}{2 {σ}^{2}} ) \qquad [ Equation 2 ]$$

The electronic device 100 may use a Gaussian function for calculating the second weights. For example, Iⱼ(x,y) may be a pixel brightness value normalized to [0, 1]. Here, the second weight may be set to have a maximum weight at a medium value of 0.5, and to decrease as it approaches 0 or 1.

In operation S1830 of FIG. 18, the electronic device 100 according to one or more embodiments of the disclosure may calculate third weights based on local variance information. The third weights may also be referred to as variance weights. Because a local window with higher local variance is highly likely to indicate a region where details are clearly visible, the electronic device 100 may calculate the third weights for assigning high weights to local window regions with high local variance. The third weight T may be represented by Equation 3 below.

$${T}_{j} ( x , y ) = Var ( {I}_{j} in n \times n window at ( x , y ) ) \qquad [ Equation 3 ]$$

Here, Var(Iⱼ in n×n window at (x,y)) may denote a variance of pixel brightness values within a local window of size n×n centered on a pixel at position (x, y).

In operation S1840 of FIG. 18, the electronic device 100 according to one or more embodiments of the disclosure may weighted-fuse first to third image data sets by using the first to third weights.

The electronic device 100 may generate a weighted fusion map by using the first to third weights. The weighted fusion map may include a final weight value W represented by Equation 4 below.

$${W}_{j} ( x , y ) = {{C}_{j} ( x , y )}^{α} \cdot {{M}_{j} ( x , y )}^{β} \cdot {{T}_{j} ( x , y )}^{γ} \qquad [ Equation 4 ]$$

Here, Cⱼ(x,y) may denote the first weight at position (x, y), Mⱼ(x,y) may denote the second weight at position (x, y), and Tⱼ(x,y) may denote the third weight at position (x, y). α may denote a first weighting parameter for the first weight, β may denote a second weighting parameter for the second weight, and γ may denote a third weighting parameter for the third weight.

The electronic device 100 may weighted-fuse the first to third image data sets by using the generated weighted fusion map (e.g., the calculated final weight value W). The electronic device 100 may generate a final sensing image (i.e., an HDR image) based on a weight-fused final image data set.

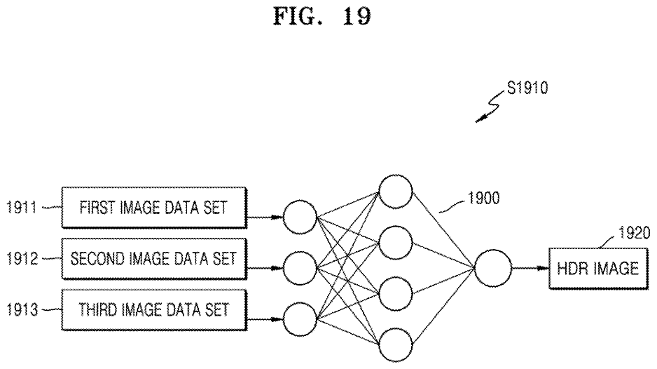

FIG. 19 is a diagram for describing an operation, performed by an electronic device, of generating an HDR image based on a plurality of light-reception signals, according to one or more embodiments of the disclosure.

Referring to FIG. 19, the operation method of the electronic device 100 according to one or more embodiments of the disclosure may further include operation S1910. In one or more embodiments of the disclosure, operation S1910 may be performed by at least one processor 130 included in the electronic device 100. Operation S1910 may be a detailed implementation of operation S1540 of FIG. 15.

In operation S1910, the electronic device 100 according to one or more embodiments of the disclosure may generate an HDR image 1920 based on a first image data set 1911, a second image data set 1912, and a third image data set 1913 by using an artificial intelligence model 1900.

In one or more embodiments of the disclosure, the electronic device 100 may input, to the artificial intelligence model 1900, the first image data set 1911, the second image data set 1912, and the third image data set 1913. The electronic device 100 may input the first to third image data sets 1911, 1912, and 1913 to the artificial intelligence model 1900 to obtain the HDR image 1920 that is output as an inference result. The artificial intelligence model 1900 may be a pre-trained model to receive the first to third image data sets 1911, 1912, and 1913 as input and output the HDR image 1920 as an inference result.

In the disclosure, a function associated with artificial intelligence may be executed through a processor and memory. The processor may include one or more processors. In this case, the one or more processors may include a general-purpose processor, such as a CPU, an AP, or a DSP, a dedicated graphics processor such as a graphics processing unit (GPU) or a vision processing unit (VPU), or a dedicated artificial intelligence processor such as a neural processing unit (NPU). The one or more processors perform control to process input data according to predefined operation rules or an artificial intelligence model stored in the memory. Alternatively, in a case where the one or more processors are dedicated artificial intelligence processors, the dedicated artificial intelligence processor may be designed with a hardware structure specialized for processing a particular artificial intelligence model.

In the disclosure, the predefined operation rules or artificial intelligence model is generated via a training process. Here, being generated via a training process may mean that predefined operation rules or artificial intelligence model set to perform desired characteristics (or purposes), is generated by training a basic artificial intelligence model by using a learning algorithm that utilizes a large amount of training data. The training process may be performed by a device itself on which artificial intelligence according to the disclosure is performed, or by a separate server and/or system. Examples of learning algorithms may include, for example, supervised learning, unsupervised learning, semi-supervised learning, and reinforcement learning, but are not limited thereto.

In the disclosure, an ‘artificial intelligence model’ may include a plurality of neural network layers. Each of the neural network layers has a plurality of weight values, and performs a neural network arithmetic operation via an arithmetic operation between an arithmetic operation result of a previous layer and the plurality of weight values. The plurality of weight values in each of the plurality of neural network layers may be optimized as a result of training the artificial intelligence model. For example, the plurality of weight values may be updated to reduce or minimize a loss or cost value obtained by the artificial intelligence model during a training process. The artificial neural network model may include, for example, a deep neural network (DNN) and may include, for example, a convolutional neural network, a recurrent neural network, a restricted Boltzmann machine, a deep belief network, a bidirectional recurrent deep neural network, a deep Q-network, or the like, but is not limited thereto.

In one or more embodiments of the disclosure, in pre-training of the artificial intelligence model 1900, images captured in ideal lighting environments may be used as ground-truth data. An ideal lighting environment may refer to an environment in which the illuminance of a region to be captured falls within a preset range at a level where saturation and low-illuminance noise do not occur within the sensing range of a light-receiving pixel.

In addition, for pre-training of the artificial intelligence model 1900, a first training image data set corresponding to the first image data set 1911, a second training image data set corresponding to the second image data set 1912, and a third training image data set corresponding to the third image data set 1913 may be used as training data. For example, the first training image data set may be data sensed under an illuminance condition (e.g., a medium/high-illuminance condition) corresponding to the first driving voltage in the first mode. The second training image data set may be data sensed under an illuminance condition (e.g., a low-illuminance condition) corresponding to the second driving voltage in the first mode. The third training image data set may be data sensed under an illuminance condition corresponding to the first driving voltage in the second mode. For example, the first training image data set may be data sensed under a high-illuminance condition, and the second and third training image data sets may be data sensed under a low-illuminance condition.

The artificial intelligence model 1900 may be a model trained to receive the first to third training image data sets as input and output a captured image based on the received first to third training image data sets. In a training process, an error between a predicted image output by the artificial intelligence model 1900 and a captured image set as ground-truth data may be calculated through a loss function, and model parameters may be adjusted to minimize the value of the loss function while performing repetitive training. The model parameters refer to internal variables of the model that are determined through a learning process using training data. The model parameters are values necessary for the model to perform prediction and may be factors that determine the performance of the model. The model parameters may be automatically adjusted during a model training process, and optimized values may be found by learning patterns of input training data. Thereafter, the gradient of the loss function may be calculated through a backpropagation algorithm, and the model parameters may be progressively updated by using gradient descent or optimization algorithms (e.g., Adam).

Through this, the artificial intelligence model 1900 may be configured to, upon receiving a plurality of image data sets 1911, 1912, and 1913 sensed under different illuminance conditions as input, output the HDR image 1920 in which saturation and low-illuminance noise are reduced such that a bright region and a dark region are simultaneously represented with high precision.

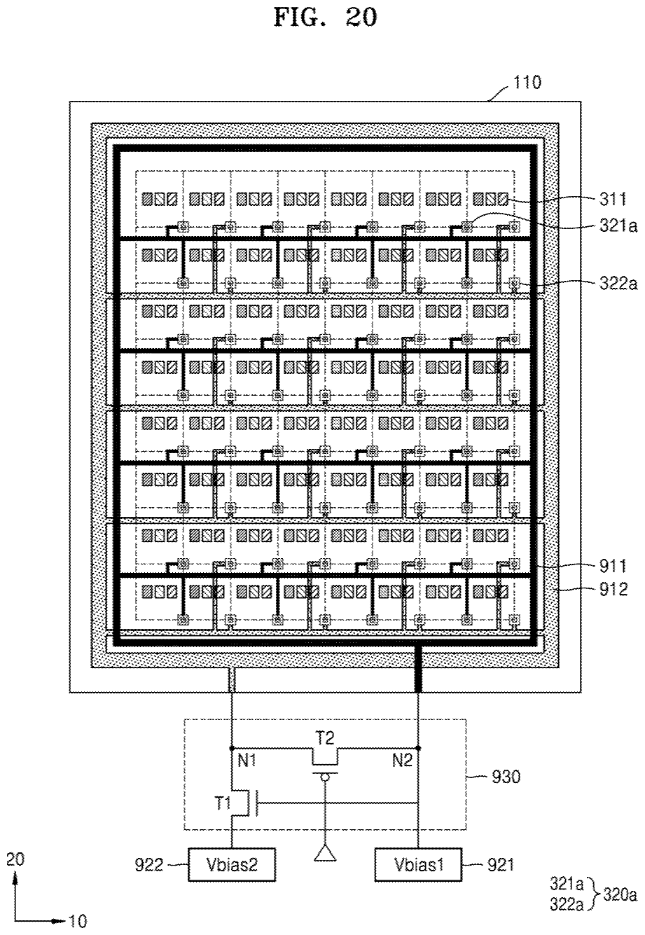

FIG. 20 is a diagram for describing a display device and a voltage control circuit, according to one or more embodiments of the disclosure. Hereinafter, the same reference numerals are assigned to the same components as those described above with reference to FIGS. 9 and 13, and redundant descriptions will be omitted.

Referring to FIG. 20, in one or more embodiments of the disclosure, the plurality of light-receiving pixels 320 may include the first-group light-receiving pixels 321 and the second-group light-receiving pixels 322. In sensing a surrounding environment at one point in time in the first mode, the first-group light-receiving pixels 321 may be light-receiving pixels to which the first driving voltage Vbias1 is applied, and the second-group light-receiving pixels 322 may be light-receiving pixels to which the second driving voltage Vbias2 different from the first driving voltage Vbias1 is applied.

In one or more embodiments of the disclosure, the first-group light-receiving pixels 321 and the second-group light-receiving pixels 322 may be alternately arranged in columns (or units of columns). Within the same column, the first-group light-receiving pixels 321 may be continuously arranged in the second direction 20 to form a first-group light-receiving pixel column, or the second-group light-receiving pixels 322 may be continuously arranged in the second direction 20 to form a second-group light-receiving pixel column. The first-group light-receiving pixel columns and the second-group light-receiving pixel columns may be alternately arranged in the first direction 10.

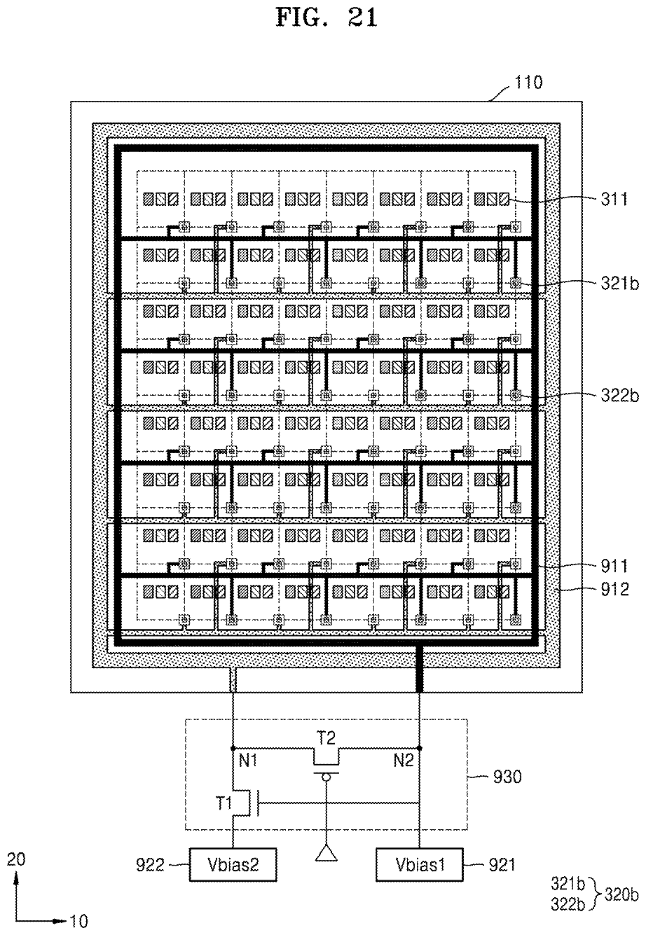

FIG. 21 is a diagram for describing a display device and a voltage control circuit, according to one or more embodiments of the disclosure. Hereinafter, the same reference numerals are assigned to the same components as those described above with reference to FIGS. 9 and 13, and redundant descriptions will be omitted.

Referring to FIG. 21, in one or more embodiments of the disclosure, the plurality of light-receiving pixels 320 may include the first-group light-receiving pixels 321 and the second-group light-receiving pixels 322. In sensing a surrounding environment at one point in time in the first mode, the first-group light-receiving pixels 321 may be light-receiving pixels to which the first driving voltage Vbias1 is applied, and the second-group light-receiving pixels 322 may be light-receiving pixels to which the second driving voltage Vbias2 different from the first driving voltage Vbias1 is applied.

In one or more embodiments of the disclosure, the first-group light-receiving pixels 321 and the second-group light-receiving pixels 322 may be alternately arranged in rows (or units of rows) and in columns (or units of columns). That is, the first-group light-receiving pixels 321 and the second-group light-receiving pixels 322 may be arranged in a grid form. Within the same column, the first-group light-receiving pixels 321 and the second-group light-receiving pixels 322 may be alternately arranged. In addition, within the same row, the first-group light-receiving pixels 321 and the second-group light-receiving pixels 322 may be alternately arranged.

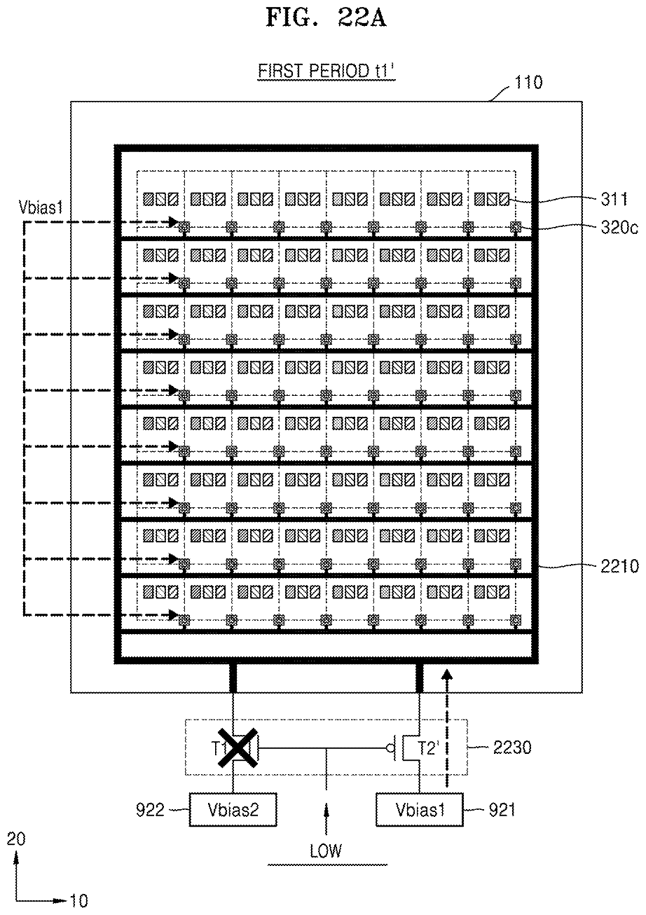

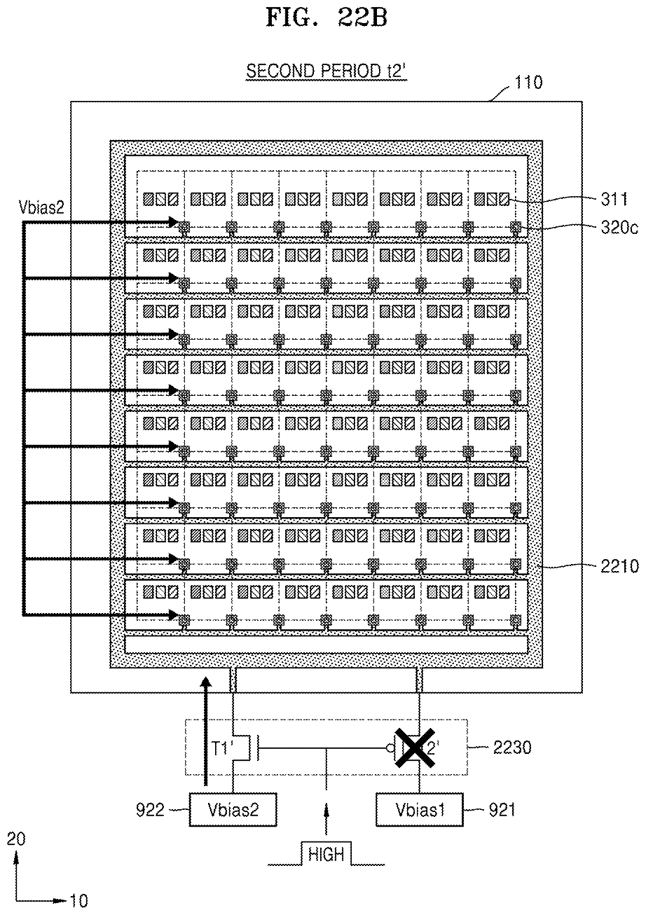

FIG. 22A is a diagram for describing a display device and a voltage control circuit, according to one or more embodiments of the disclosure. FIG. 22B is a diagram for describing a display device and a voltage control circuit, according to one or more embodiments of the disclosure.

Referring to FIGS. 22A and 22B together, the display device 110 according to one or more embodiments of the disclosure may include a plurality of light-receiving pixels 320c and a voltage line 2210 electrically connected to the plurality of light-receiving pixels 320c. The light-receiving pixels 320c may be arranged in the first direction 10 and the second direction 20. Here, all of the light-receiving pixels 320c may be electrically connected to the same voltage line 2210.

In one or more embodiments of the disclosure, the electronic device 100 may include the first voltage supply 921 configured to apply the first driving voltage Vbias1 and the second voltage supply 922 configured to apply the second driving voltage Vbias2. The first driving voltage Vbias1 may be a variable voltage. For example, the first driving voltage Vbias1 may be determined to have a voltage value that enables the light-receiving pixels 320c to detect light under a medium-illuminance condition or a high-illuminance condition. The second driving voltage Vbias2 may be a fixed voltage. For example, the second driving voltage Vbias2 may be determined to have a voltage value that enables the light-receiving pixels 320c to detect light under a low-illuminance condition. The magnitude (or absolute value) of the second driving voltage Vbias2 may be greater than the magnitude (or absolute value) of the first driving voltage Vbias1. However, one or more embodiments of the disclosure is not limited thereto, and both the first driving voltage Vbias1 and the second driving voltage Vbias2 may be variable voltages or fixed voltages.

In one or more embodiments of the disclosure, the electronic device 100 may further include a voltage control circuit 2230. The voltage control circuit 2230 may be electrically connected to the voltage line 2210 to control a driving voltage applied to the voltage line 2210.

In one or more embodiments of the disclosure, the voltage control circuit 2230 may include a first transistor T1′ and a second transistor T2′. The first transistor T1′ may be electrically connected between the first voltage supply 921 and the voltage line 2210. The second transistor T2′ may be electrically connected between the second voltage supply 922 and the voltage line 2210.

The first transistor T1′ may include a gate electrode that receives a gate signal, a first electrode that is connected to the second voltage supply 922 (or receives the second driving voltage Vbias2), and a second electrode that is connected to the voltage line 2210. The first transistor T1′ may operate in an off-state based on a gate signal of a low level being applied to the gate electrode. The first transistor T1′ may operate in an on-state based on a gate signal of a high level being applied to the gate electrode. For example, the first transistor T1′ may be an n-type transistor.

The second transistor T2′ may include a gate electrode that receives a gate signal, a first electrode that is connected to the first voltage supply 921 (or receives the first driving voltage Vbias1), and a second electrode that is connected to the voltage line 2210. The second transistor T2′ may operate in an on-state based on a gate signal of a low level being applied to the gate electrode. The second transistor T2′ may operate in an off-state based on a gate signal of a high level being applied to the gate electrode. For example, the second transistor T2′ may be a p-type transistor.

In one or more embodiments of the disclosure, the driving voltage applied to the light-receiving pixels 320c may be controlled through time division of each frame. For example, a one-frame period may be time-divided into a first-sensitivity sensing period t1′ and a second-sensitivity sensing period t2′. In the first-sensitivity sensing period t1′, the electronic device 100 may operate in a first sensitivity mode for performing sensing under a first sensitivity condition, and in the second-sensitivity sensing period t2′, the electronic device 100 may operate in a second sensitivity mode for performing sensing under a second sensitivity condition that is different from the first sensitivity condition.

During the first-sensitivity sensing period t1′, the electronic device 100 may supply a driving signal corresponding to the first sensitivity mode to the voltage control circuit 2230. For example, as illustrated in FIG. 22A, during the first-sensitivity sensing period t1′, a low-level gate signal may be supplied to the gate electrode of the first transistor T1′ and the gate electrode of the second transistor T2′. Accordingly, the first transistor T1′ may be turned off, and the second transistor T2′ may be turned on. As the first transistor T1′ is turned off, the second voltage supply 922 and the voltage line 2210 may be electrically disconnected from each other. As the second transistor T2′ is turned on, the first voltage supply 921 and the voltage line 2210 may be electrically connected to each other. Accordingly, the first driving voltage Vbias1 may be applied to the light-receiving pixels 320c. In the first-sensitivity sensing period t1′, light may be detected under a sensitivity condition (e.g., a low-sensitivity condition for sensing a medium-illuminance region or a high-illuminance region) corresponding to the first driving voltage Vbias1.

During the second-sensitivity sensing period t2′, the electronic device 100 may supply a driving signal corresponding to the second sensitivity mode to the voltage control circuit 2230. For example, as illustrated in FIG. 22B, during the second-sensitivity sensing period t2′, a high-level gate signal may be supplied to the gate electrode of the first transistor T1′ and the gate electrode of the second transistor T2′. Accordingly, as illustrated in FIG. 22B, when a high-level gate signal is applied to the gate electrode of the first transistor T1′ and the gate electrode of the second transistor T2′, the first transistor T1′ may be turned on and the second transistor T2′ may be turned off. As the first transistor T l′ is turned on, the second voltage supply 922 and the voltage line 2210 may be electrically connected to each other. As the second transistor T2′ is turned off, the first voltage supply 921 and the voltage line 2210 may be electrically disconnected from each other. Accordingly, the second driving voltage Vbias2 may be applied to the light-receiving pixels 320c. In the second-sensitivity sensing period t2′, light may be detected under a sensitivity condition (e.g., a high-sensitivity condition for sensing a low-illuminance region) corresponding to the second driving voltage Vbias2.

The configuration of the voltage control circuit 2230 is not limited thereto, and any circuit configuration may be employed in which, based on a particular input signal, the first voltage supply 921 or the second voltage supply 922 may be selectively electrically connected to the voltage line 2210.

Within a one-frame period, the electronic device 100 may obtain, during the first-sensitivity sensing period t1′, first light-reception signals captured under the first sensitivity condition, and obtain, during the second-sensitivity sensing period t2′, second light-reception signals captured under the second sensitivity condition. The electronic device 100 may generate an HDR image based on the obtained first light-reception signals and second light-reception signals.

According to one or more embodiments of the disclosure, the electronic device 100 may obtain a sensing image in which a bright region and a dark region are simultaneously represented with high precision, by applying a plurality of different driving voltages to the plurality of light-receiving pixels 320c through time division of each frame.

To solve the above-described technical issues, one or more embodiments of the disclosure provides an electronic device 100.

In one or more embodiments of the disclosure, The electronic device 100 may include a display device 110, memory 120 storing a plurality of instructions, and at least one processor 130 including processing circuitry. In one or more embodiments of the disclosure, the display device 110 may include a pixel layer 540 including a plurality of light-emitting pixels 311 and a plurality of light-receiving pixels 320, and a lens layer 570 arranged above the pixel layer 540 and including a plurality of lenses 330 respectively corresponding to the plurality of light-receiving pixels 320. In one or more embodiments of the disclosure, the plurality of light-receiving pixels 320 may include first-group light-receiving pixels 321 and second-group light-receiving pixels 322.

In one or more embodiments of the disclosure, the at least one processor 130 may individually or collectively execute the plurality of instructions to cause the electronic device 100 to obtain first light-reception signals from first-group light-receiving pixels 321 among the plurality of light-receiving pixels 320 and second light-reception signals from second-group light-receiving pixels 322 among the plurality of light-receiving pixels 320, by applying a first driving voltage to the first-group light-receiving pixels 321 and applying a second driving voltage having a voltage value different from a voltage value of the first driving voltage to the second-group light-receiving pixels 322. In one or more embodiments of the disclosure, the at least one processor 130 may individually or collectively execute the plurality of instructions to cause the electronic device 100 to generate an HDR image based on the obtained first light-reception signals and the obtained second light-reception signals.

In one or more embodiments of the disclosure, the at least one processor 130 may individually or collectively execute the plurality of instructions to cause the electronic device 100 to obtain third light-reception signals from the plurality of light-receiving pixels 320 by applying a driving voltage (e.g., a driving voltage of a same level) to the plurality of light-receiving pixels 320 (e.g., all of the plurality of light-receiving pixels 320). In one or more embodiments of the disclosure, the at least one processor 130 may individually or collectively execute the plurality of instructions to cause the electronic device 100 to generate a high-resolution image having a resolution higher than a resolution of the HDR image, based on the obtained third light-reception signals.

In one or more embodiments of the disclosure, the at least one processor 130 may individually or collectively execute the plurality of instructions to cause the electronic device 100 to, based on receiving a user input for selecting a first mode, apply the first driving voltage to the first-group light-receiving pixels 321 and apply the second driving voltage to the second-group light-receiving pixels 322. In one or more embodiments of the disclosure, the at least one processor 130 may individually or collectively execute the plurality of instructions to cause the electronic device 100 to, based on receiving a user input for selecting a second mode, apply the driving voltage (e.g., the driving voltage of the same level) to the plurality of light-receiving pixels 320 (e.g., all of the plurality of light-receiving pixels 320).

In one or more embodiments of the disclosure, the electronic device 100 may further include a first voltage line 911 electrically connected to the first-group light-receiving pixels 321, a first voltage supply 921 configured to provide the first driving voltage, a second voltage line 912 electrically connected to the second-group light-receiving pixels 322, and a second voltage supply 922 configured to provide the second driving voltage. The first driving voltage may be a variable voltage. The second driving voltage may be a fixed voltage.

In one or more embodiments of the disclosure, the electronic device 100 may further include a first transistor T1 electrically connected between the second voltage supply 922 and the second voltage line 912, and a second transistor T2 electrically connected between a first node N1 where the first transistor T1 and the second voltage line 912 are connected to each other, and a second node N2 where the first voltage supply 921 and the first voltage line 911 are connected to each other. The first transistor T1 may be configured to operate in an on-state based on a first voltage level being applied, and operate in an off-state based on a second voltage level different from the first voltage level being applied. The second transistor T2 may be configured to operate in an off-state based on the first voltage level being applied, and operate in an on-state based on the second voltage level being applied.

In one or more embodiments of the disclosure, the at least one processor 130 may individually or collectively execute the plurality of instructions to cause the electronic device 100 to, based on receiving the user input for selecting the first mode, apply the first driving voltage to the first-group light-receiving pixels 321 through the first voltage line 911 and apply the second driving voltage to the second-group light-receiving pixels 322 through the second voltage line 912, by applying the first voltage level to each of the first transistor T1 and the second transistor T2.

In one or more embodiments of the disclosure, the at least one processor 130 may individually or collectively execute the plurality of instructions to cause the electronic device 100 to, based on receiving the user input for selecting the second mode, apply the first driving voltage to the first-group light-receiving pixels 321 through the first voltage line 911 and apply the first driving voltage to the second-group light-receiving pixels 322 through the second voltage line 912, by applying the second voltage level to each of the first transistor T1 and the second transistor T2.

In one or more embodiments of the disclosure, the at least one processor 130 may individually or collectively execute the plurality of instructions to cause the electronic device 100 to obtain, in a first period of each frame, a first image data set based on the first light-reception signals and a second image data set based on the second light-reception signals by applying the first driving voltage to the first-group light-receiving pixels 321 and applying the second driving voltage to the second-group light-receiving pixels 322. In one or more embodiments of the disclosure, the at least one processor 130 may individually or collectively execute the plurality of instructions to cause the electronic device 100 to obtain, in a second period of each frame, a third image data set based on the third light-reception signals by applying the driving voltage (e.g., the driving voltage of the same level) to the plurality of light-receiving pixels 320 (e.g., all of the plurality of light-receiving pixels 320). In one or more embodiments of the disclosure, the at least one processor 130 may individually or collectively execute the plurality of instructions to cause the electronic device 100 to generate the HDR image based on the first image data set, the second image data set, and the third image data set.

In one or more embodiments of the disclosure, the at least one processor 130 may individually or collectively execute the plurality of instructions to cause the electronic device 100 to upscale each of the second image data set and the third image data set by a factor of 2. In one or more embodiments of the disclosure, the at least one processor 130 may individually or collectively execute the plurality of instructions to cause the electronic device 100 to generate the HDR image by combining the first image data set, the upscaled second image data set, and the upscaled third image data set.

In one or more embodiments of the disclosure, the at least one processor 130 may individually or collectively execute the plurality of instructions to cause the electronic device 100 to downscale the first image data set by a factor of 0.5. In one or more embodiments of the disclosure, the at least one processor 130 may individually or collectively execute the plurality of instructions to cause the electronic device 100 to generate the HDR image by combining the downscaled first image data set, the second image data set, and the third image data set.

In one or more embodiments of the disclosure, the at least one processor 130 may individually or collectively execute the plurality of instructions to cause the electronic device 100 to generate a radiance map based on the first image data set, the second image data set, and the third image data set. In one or more embodiments of the disclosure, the at least one processor 130 may individually or collectively execute the plurality of instructions to cause the electronic device 100 to generate the HDR image by performing tone mapping based on the radiance map.

In one or more embodiments of the disclosure, the at least one processor 130 may individually or collectively execute the plurality of instructions to cause the electronic device 100 to generate the HDR image by weighted-fusing the first image data set, the second image data set, and the third image data set by using a final weight value calculated by reflecting a first weight based on contrast information, a second weight based on brightness information, and a third weight based on local variance information.

In one or more embodiments of the disclosure, the at least one processor 130 may individually or collectively execute the plurality of instructions to cause the electronic device 100 to generate the HDR image by inputting, to an artificial intelligence model 1900, the first image data set, the second image data set, and the third image data set.

In one or more embodiments of the disclosure, the first-group light-receiving pixels 321 and the second-group light-receiving pixels 322 may be alternately arranged in rows (or units of rows) or columns (or in units of columns).

In one or more embodiments of the disclosure, the first-group light-receiving pixels 321 and the second-group light-receiving pixels 322 may be alternately arranged in rows (or units of rows) and in columns (or units of columns).

To solve the above-described technical issues, one or more embodiments of the disclosure provides an operation method of the electronic device 100 (or a method of operating the electronic device 100).

In one or more embodiments of the disclosure, the operation method of the electronic device 100 may include obtaining first light-reception signals from first-group light-receiving pixels among the plurality of light-receiving pixels and second light-reception signals from second-group light-receiving pixels among the plurality of light-receiving pixels, by applying a first driving voltage to the first-group light-receiving pixels and applying a second driving voltage having a voltage value different from a voltage value of the first driving voltage to the second-group light-receiving pixels (S810).

In one or more embodiments of the disclosure, the operation method of the electronic device 100 may include generating an HDR image based on the obtained first light-reception signals and the obtained second light-reception signals (S820).

In one or more embodiments of the disclosure, the operation method of the electronic device 100 may include obtaining third light-reception signals from the plurality of light-receiving pixels by applying a driving voltage (e.g., a driving voltage of a same level) to the plurality of light-receiving pixels (e.g., all of the plurality of light-receiving pixels) (S1210). In one or more embodiments of the disclosure, the operation method of the electronic device 100 may include generating a high-resolution image having a resolution higher than a resolution of the HDR image, based on the obtained third light-reception signals (S1220).

In one or more embodiments of the disclosure, the obtaining of the first light-reception signals and the second light-reception signals by applying the first driving voltage to the first-group light-receiving pixels and applying the second driving voltage to the second-group light-receiving pixels (S810) may include, based on receiving a user input for selecting a first mode, applying the first driving voltage to the first-group light-receiving pixels and applying the second driving voltage to the second-group light-receiving pixels (S1420).

In one or more embodiments of the disclosure, the obtaining of the third light-reception signals by applying the driving voltage (e.g., the driving voltage of the same level) to the plurality of light-receiving pixels (e.g., all of the plurality of light-receiving pixels) (S1210) may include, based on receiving a user input for selecting a second mode, applying the driving voltage (e.g., the driving voltage of the same level) to the plurality of light-receiving pixels (e.g., all of the plurality of light-receiving pixels) (S1430).

In one or more embodiments of the disclosure, the operation method of the electronic device 100 may include obtaining, in a first period of each frame, a first image data set based on the first light-reception signals and a second image data set based on the second light-reception signals by applying the first driving voltage to the first-group light-receiving pixels and applying the second driving voltage to the second-group light-receiving pixels (S1510). In one or more embodiments of the disclosure, the operation method of the electronic device 100 may include obtaining, in a second period of each frame, a third image data set based on the third light-reception signals by applying the driving voltage (e.g., the driving voltage of the same level) to the plurality of light-receiving pixels (e.g., all of the plurality of light-receiving pixels) (S1520). In one or more embodiments of the disclosure, the operation method of the electronic device 100 may include generating the HDR image based on the first image data set, the second image data set, and the third image data set (S1540).

A machine-readable storage medium may be provided in the form of a non-transitory storage medium. Here, the term ‘non-transitory storage medium’ refers to a tangible device and does not include a signal (e.g., an electromagnetic wave), and the term ‘non-transitory storage medium’ does not distinguish between a case where data is stored in a storage medium semi-permanently and a case where data is stored temporarily. For example, the ‘non-transitory storage medium’ may include a buffer in which data is temporarily stored.

According to one or more embodiments of the disclosure, methods according to the embodiment disclosed herein may be included in a computer program product and then provided. The computer program product may be traded as a commodity between sellers and buyers. The computer program product may be distributed in the form of a machine-readable storage medium (e.g., a compact disc ROM (CD-ROM)), or may be distributed online (e.g., downloaded or uploaded) through an application store or directly between two user devices (e.g., smart phones). In a case of online distribution, at least a portion of the computer program product (e.g., a downloadable app) may be temporarily stored in a machine-readable storage medium such as a manufacturer's server, an application store's server, or memory of a relay server.

What is claimed is:

1. An electronic device comprising:
a display device;
memory storing instructions; and
at least one processor comprising processing circuitry,
wherein the display device comprises:
a pixel layer comprising:
a plurality of light-emitting pixels; and
a plurality of light-receiving pixels comprising:
first-group light-receiving pixels; and
second-group light-receiving pixels; and
a lens layer on the pixel layer and comprising a plurality of lenses respectively corresponding to the plurality of light-receiving pixels, and
wherein the at least one processor individually or collectively executes the instructions to cause the electronic device to:
obtain, by applying a first driving voltage to the first-group light-receiving pixels and applying a second driving voltage having a voltage value different from a voltage value of the first driving voltage to the second-group light-receiving pixels:
first light-reception signals from the first-group light-receiving pixels; and
second light-reception signals from the second-group light-receiving pixels; and
generate a high dynamic range (HDR) image based on the obtained first light-reception signals and the obtained second light-reception signals.

2. The electronic device of claim 1, wherein the at least one processor further individually or collectively executes the instructions to cause the electronic device to:
obtain, by applying a driving voltage of a same level to all of the plurality of light-receiving pixels, third light-reception signals from the plurality of light-receiving pixels; and
generate, based on the obtained third light-reception signals, a high-resolution image having a resolution higher than a resolution of the HDR image.

3. The electronic device of claim 2, wherein the at least one processor further individually or collectively executes the instructions to cause the electronic device to:
based on receiving a user input for selecting a first mode:
apply the first driving voltage to the first-group light-receiving pixels; and
apply the second driving voltage to the second-group light-receiving pixels; and
based on receiving a user input for selecting a second mode, apply the driving voltage of the same level to all of the plurality of light-receiving pixels.

4. The electronic device of claim 1, further comprising:
a first voltage line electrically connected to the first-group light-receiving pixels;
a first voltage supply configured to provide the first driving voltage;
a second voltage line electrically connected to the second-group light-receiving pixels; and
a second voltage supply configured to provide the second driving voltage,
wherein the first driving voltage is a variable voltage, and the second driving voltage is a fixed voltage.

5. The electronic device of claim 4, further comprising:
a first transistor electrically connected between the second voltage supply and the second voltage line; and
a second transistor electrically connected between a first node where the first transistor and the second voltage line are connected to each other, and a second node where the first voltage supply and the first voltage line are connected to each other,
wherein the first transistor is configured to:
operate in an on-state based on a first voltage level being applied, and
operate in an off-state based on a second voltage level different from the first voltage level being applied, and
wherein the second transistor is configured to:
operate in an off-state based on the first voltage level being applied, and
operate in an on-state based on the second voltage level being applied.

6. The electronic device of claim 5, wherein the at least one processor further individually or collectively executes the instructions to cause the electronic device to:
based on receiving the user input for selecting a first mode, by applying the first voltage level to each of the first transistor and the second transistor:
apply the first driving voltage to the first-group light-receiving pixels through the first voltage line; and
apply the second driving voltage to the second-group light-receiving pixels through the second voltage line.

7. The electronic device of claim 6, wherein the at least one processor further individually or collectively executes the instructions to cause the electronic device to:
based on receiving the user input for selecting a second mode, by applying the second voltage level to each of the first transistor and the second transistor:
apply the first driving voltage to the first-group light-receiving pixels through the first voltage line; and
apply the first driving voltage to the second-group light-receiving pixels through the second voltage line.

8. The electronic device of claim 1, wherein the at least one processor further individually or collectively executes the instructions to cause the electronic device to:
obtain, in a first period of each frame, by applying the first driving voltage to the first-group light-receiving pixels and applying the second driving voltage to the second-group light-receiving pixels;
a first image data set based on the first light-reception signals; and
a second image data set based on the second light-reception signals;
obtain, in a second period of each frame, a third image data set based on a third light-reception signals by applying a driving voltage of a same level to all of the plurality of light-receiving pixels; and
generate the HDR image based on the first image data set, the second image data set, and the third image data set.

9. The electronic device of claim 8, wherein the at least one processor further individually or collectively executes the instructions to cause the electronic device to:
upscale each of the second image data set and the third image data set by a factor of 2; and
generate the HDR image by combining the first image data set, the upscaled second image data set, and the upscaled third image data set.

10. The electronic device of claim 8, wherein the at least one processor further individually or collectively executes the instructions to cause the electronic device to:
downscale the first image data set by a factor of 0.5; and
generate the HDR image by combining the downscaled first image data set, the second image data set, and the third image data set.

11. The electronic device of claim 8, wherein the at least one processor individually or collectively executes the instructions to cause the electronic device to:
generate a radiance map based on the first image data set, the second image data set, and the third image data set; and
generate the HDR image by performing tone mapping based on the radiance map.

12. The electronic device of claim 8, wherein the at least one processor individually or collectively executes the instructions to cause the electronic device to:
generate the HDR image by weighted-fusing the first image data set, the second image data set, and the third image data set by using a final weight value calculated by reflecting a first weight based on contrast information, a second weight based on brightness information, and a third weight based on local variance information.

13. The electronic device of claim 8, wherein the at least one processor individually or collectively executes the instructions to cause the electronic device to:
generate the HDR image by inputting, to an artificial intelligence model, the first image data set, the second image data set, and the third image data set.

14. The electronic device of claim 1, wherein the first-group light-receiving pixels and the second-group light-receiving pixels are alternately arranged in rows or in columns.

15. The electronic device of claim 1, wherein the first-group light-receiving pixels and the second-group light-receiving pixels are alternately arranged in rows and in columns.

16. The electronic device of claim 1, wherein the plurality of light-receiving pixels are arranged to correspond, respectively, to the plurality of light-emitting pixels.

17. A method of operating an electronic device comprising a display device,
wherein the display device comprises:
a pixel layer comprising a plurality of light-emitting pixels and a plurality of light-receiving pixels; and
a lens layer on the pixel layer and comprising a plurality of lenses respectively corresponding to the plurality of light-receiving pixels, and
the operation method comprising:
obtaining, by applying a first driving voltage to the first-group light-receiving pixels and applying a second driving voltage having a voltage value different from a voltage value of the first driving voltage to the second-group light-receiving pixels:
first light-reception signals from first-group light-receiving pixels among the plurality of light-receiving pixels; and
second light-reception signals from second-group light-receiving pixels among the plurality of light-receiving pixels; and
generating a high dynamic range (HDR) image based on the obtained first light-reception signals and the obtained second light-reception signals.

18. The method of claim 17, further comprising:
obtaining, by applying a driving voltage of a same level to all of the plurality of light-receiving pixels, third light-reception signals from the plurality of light-receiving pixels; and
generating, based on the obtained third light-reception signals, a high-resolution image having a resolution higher than a resolution of the HDR image.

19. The method of claim 18, wherein the obtaining the first light-reception signals and the second light-reception signals comprises:
based on receiving a user input for selecting a first mode:
applying the first driving voltage to the first-group light-receiving pixels; and
applying the second driving voltage to the second-group light-receiving pixels, and
the obtaining the third light-reception signals comprises:
based on receiving a user input for selecting a second mode, applying the driving voltage of the same level to all of the plurality of light-receiving pixels.

20. The method of claim 17, further comprising:
obtaining, in a first period of each frame, by applying the first driving voltage to the first-group light-receiving pixels and applying the second driving voltage to the second-group light-receiving pixels:
a first image data set based on the first light-reception signals; and
a second image data set based on the second light-reception signals;
obtaining, in a second period of each frame, a third image data set based on the third light-reception signals by applying the driving voltage of the same level to all of the plurality of light-receiving pixels; and
generating the HDR image based on the first image data set, the second image data set, and the third image data set.
